(19) United States
(12) Patent Application Publication
(10) Pub. No.: US 2026/0358657 A1
(43) Pub. Date: Nov. 12, 2026

(54) LIQUID CRYSTAL DISPLAY PANEL AND METHOD FOR PRODUCING LIQUID CRYSTAL DISPLAY PANEL

(71) Applicant: Sharp Kabushiki Kaisha, Osaka (JP)

(72) Inventors: MASANOBU MIZUSAKI, Osaka (JP); Mariko Honda, Osaka (JP); Kazuhito Matsumoto, Osaka (JP); Takatoshi Hirooka, Osaka (JP)

(21) Appl. No.: 19/654,291

(22) Filed: Apr. 21, 2026

(30) Foreign Application Priority Data
Apr. 23, 2025 (JP) 2025-071284

(51) Int. Cl. G02F 1/1333; G02F 1/1335; G02F 1/1337; G02F 1/1362; G03F 7/039; G03F 7/09

(52) U.S. Cl. CPC G02F 1/133357; G02F 1/133516; G02F 1/133711; G02F 1/136227; G03F 7/039; G03F 7/094; G02F 2201/123

(57) ABSTRACT

A liquid crystal display panel that includes: a first substrate; a second substrate; and a liquid crystal layer sandwiched between the first substrate and the second substrate. The first substrate includes, sequentially toward the liquid crystal layer: a switching element; a color filter layer; a planarization layer formed from a resist composition that contains a positive resist and a crosslinkable polymer containing a crosslinkable group; a pixel electrode; a connection electrode connecting the switching element and the pixel electrode via an opening formed through the color filter layer and the planarization layer; and a connection region where the pixel electrode and the connection electrode are in contact with each other. The planarization layer has a taper angle θ of 30° or greater and 50° or less at the opening. An overlap length from one end to the other end of the connection region is 1 μm or greater and 3 μm or less.

### CROSS-REFERENCE TO RELATED APPLICATIONS

The present application claims priority under 35 U.S.C. § 119 to Japanese Patent Application No. 2025-071284 filed on Apr. 23, 2025, the contents of which are incorporated herein by reference in their entirety.

### BACKGROUND

### Technical Field

The following disclosure relates to liquid crystal display panels and methods for producing the liquid crystal display panels.

### Description of Related Art

Liquid crystal display panels are display panels utilizing a liquid crystal composition to display images. A typical display method thereof involves applying a voltage to a liquid crystal composition sealed between a pair of substrates to change the alignment of liquid crystal molecules in the liquid crystal composition according to the applied voltage, thereby controlling the amount of transmitted light. Such liquid crystal display panels feature a thin profile, light weight, and low power consumption, and are therefore used in a wide variety of fields.

Techniques relating to liquid crystal display panels have been disclosed. JP 5676891 B discloses a photosensitive resin composition for forming an interlayer organic insulating film for a TFT-LCD, which contains a UV stabilizer and a radical scavenger, each in an amount of 1 to 10% by mass.

JP 2023-169473 A discloses an active matrix substrate, including: a substrate that is transparent; and a plurality of pixels positioned on the substrate. Each pixel includes: a TFT positioned on the substrate; a first color filter layer disposed on the substrate so as to cover the TFT; a contact hole being provided in the first color filter layer; a pixel electrode that is positioned on a bottom face and a side face of the contact hole and on the first color filter layer, and that is electrically connected to the TFT via the contact hole; and a second color filter layer disposed within the contact hole.

WO 2011-046230 discloses a radiation sensitive resin composition containing: [A] an alkali-soluble resin; [B] a 1,2-quinonediazide compound; and [C] a radical trapping agent.

JP 2022-24991 A discloses a liquid crystal display device sequentially including: a first substrate; a first alignment layer; a liquid crystal layer containing liquid crystal molecules horizontally aligned with no voltage applied; a second alignment layer; and a second substrate including a pixel electrode and a common electrode. The liquid crystal display device further includes a reflective layer disposed in at least part of a pixel at a position closer to a back surface than the first alignment layer, the liquid crystal layer, the second alignment layer, the pixel electrode, and the common electrode, at least one alignment layer of the first alignment layer or the second alignment layer having an azimuthal anchoring energy value of less than 1×10⁻⁴ J/m².

JP 2024-46379 A discloses an active matrix substrate including: a substrate; and a plurality of pixels located on the substrate. Each of the plurality of pixels includes: an oxide semiconductor layer; a first insulator covering the oxide semiconductor layer; a first contact hole located at the first insulator; a first extraction electrode located on the first insulator and in the first contact hole and connected to the oxide semiconductor layer; a second insulator covering the first extraction electrode; a second contact hole located at the second insulator; a second extraction electrode located on the second insulator and in the second contact hole and connected to the first extraction electrode; and a pixel electrode connected to the second extraction electrode. The first extraction electrode and the second extraction electrode are light-transmissive. A portion of a side surface of at least one of the first contact hole or the second contact hole is not covered with the first extraction electrode and the second extraction electrode.

### SUMMARY

When a high-resolution liquid crystal display panel employs a color filter on array (COA) substrate, the transmission area of the COA substrate is not sufficiently large, resulting in low transmittance. In addition, high-resolution liquid crystal display panels are prone to open-circuit defects, and therefore suppression of such open-circuit defects is required.

In view of the above circumstances, the present disclosure aims to provide a liquid crystal display panel having favorable transmittance and suppressed open-circuit defects, and a method for producing the liquid crystal display panel.

(1) One embodiment of the present invention is directed to a liquid crystal display panel including: a first substrate; a second substrate opposite to the first substrate; and a liquid crystal layer sandwiched between the first substrate and the second substrate, the first substrate including, sequentially toward the liquid crystal layer: a switching element; a color filter layer; a planarization layer formed from a resist composition that contains a positive resist and a crosslinkable polymer having a crosslinkable group; and a pixel electrode, the first substrate further including: a connection electrode connecting the switching element and the pixel electrode via an opening formed through the color filter layer and the planarization layer; and a connection region in which the pixel electrode and the connection electrode are in contact with each other, wherein the planarization layer has a taper angle θ of 30° or greater and 50° or less at the opening, and an overlap length, defined as a length from one end to the other end of the connection region in a vertical direction of a screen of the liquid crystal display panel or in a horizontal direction of the screen, is 1 μm or greater and 3 μm or less.

(2) In an embodiment of the present invention, the liquid crystal display panel includes the structure (1), and further includes a photoalignment film between the first substrate and the liquid crystal layer, wherein the photoalignment film contains a photoalignment film polymer having at least one functional group selected from the group consisting of a photodegradable functional group, a photodimerizable functional group, and a photoisomerizable functional group.

(3) In an embodiment of the present invention, the liquid crystal display panel includes the structure (2), and the photoalignment film polymer has at least one group selected from the group consisting of a cyclobutane group, an azobenzene group, a cinnamate group, and a coumarin group.

(4) In an embodiment of the present invention, the liquid crystal display panel includes the structure (1), (2), or (3), and the planarization layer exhibits a molecular weight distribution of 10 or greater and 20 or less.

(5) In an embodiment of the present invention, the liquid crystal display panel includes the structure (1), (2), (3), or (4), and the positive resist is at least one compound selected from the group consisting of naphthoquinone diazide and a naphthoquinone diazide derivative.

(6) In an embodiment of the present invention, the liquid crystal display panel includes the structure (1), (2), (3), (4), or (5), and the planarization layer contains a radical scavenger having a radical-trapping group.

(7) In an embodiment of the present invention, the liquid crystal display panel includes the structure (6), and the radical-trapping group is a hindered amine group.

(8) In an embodiment of the present invention, the liquid crystal display panel includes the structure (7), and the hindered amine group has at least one structure selected from the group consisting of structures represented by the following chemical formula (A11) and structures represented by the following chemical formula (A12):

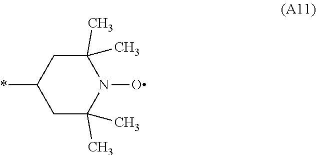

wherein * represents a bonding site,

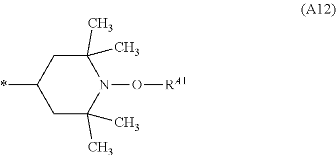

wherein R^{A1} represents a monovalent alkyl group, and * represents a bonding site.

(9) In an embodiment of the present invention, the liquid crystal display panel includes the structure (6), (7), or (8), and the radical-trapping group is a hydrazyl radical group.

(10) In an embodiment of the present invention, the liquid crystal display panel includes the structure (9), and the hydrazyl radical group has a structure represented by the following chemical formula (B):

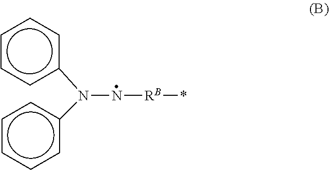

wherein R^{B} represents a divalent organic group, and * represents a bonding site.

(11) In an embodiment of the present invention, the liquid crystal display panel includes the structure (6), (7), (8), (9), or (10), and the planarization layer contains the radical scavenger in an amount greater than 0 wt % and less than 16 wt %.

(12) In an embodiment of the present invention, the liquid crystal display panel includes the structure (1), (2), (3), (4), (5), (6), (7), (8), (9), (10), or (11), and further includes a radical-trapping layer having a radical-trapping function between the color filter layer and the planarization layer.

(13) In an embodiment of the present invention, the liquid crystal display panel includes the structure (12), and the radical-trapping layer contains a radical-trapping layer polymer having at least one group selected from the group consisting of hindered amine groups and hydrazyl radical groups.

(14) In an embodiment of the present invention, the liquid crystal display panel includes the structure (13), and the radical-trapping layer polymer is an imide-based polymer, a siloxane-based polymer, an amide-based polymer, an acrylic-based polymer, or a methacrylic-based polymer.

(15) In an embodiment of the present invention, the liquid crystal display panel includes the structure (13) or (14), wherein the radical-trapping layer polymer has a structure represented by the following chemical formula (P1):

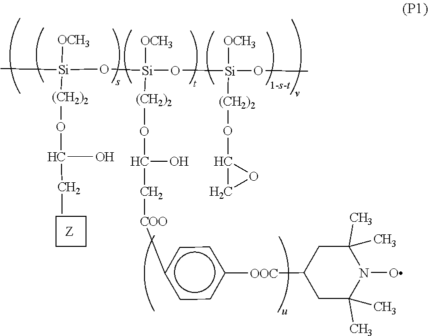

wherein s and t represent mass fractions of respective structural units in a main chain, s represents a real number greater than 0 and 0.5 or less, t represents a real number of 0.03 or greater and 0.3 or less, s+t<1, u represents an integer of 0 or greater and 18 or less, v represents an integer of 3 or greater, and Z represents a C3-C25 alkyl group.

(16) In an embodiment of the present invention, the liquid crystal display panel includes the structure (12), (13), (14), or (15), and the radical-trapping layer has a thickness greater than 0 nm and 300 nm or less.

(17) Another embodiment of the present invention is directed to a method for producing a liquid crystal display panel including: a first substrate including a switching element; a second substrate opposite to the first substrate; and a liquid crystal layer sandwiched between the first substrate and the second substrate, the method including: a color filter layer formation step including forming a color filter layer provided with a first opening above the switching element; a planarization layer formation step including applying a resist composition that contains a positive resist and a crosslinkable polymer having a crosslinkable group to a side of the color filter layer opposite to the switching element, performing an exposure treatment and a development treatment, and then performing a heat treatment, thereby forming a planarization layer provided with a second opening that overlaps the first opening in a plan view; a connection electrode formation step including forming a connection electrode that extends from the switching element to a surface of the planarization layer opposite to the color filter layer through an opening defined by the first opening and the second opening; and a pixel electrode formation step including forming a pixel electrode that is in contact with the connection electrode, on a side of the connection electrode opposite to the planarization layer, wherein the planarization layer has a taper angle θ of 30° or greater and 50° or less at the opening, and an overlap length is 1 μm or greater and 3 μm or less, the overlap length being defined as a length, measured in a vertical direction of a screen of the liquid crystal display panel or in a horizontal direction of the screen, from one end to the other end of a connection region in which the connection electrode and the pixel electrode are in contact with each other.

(18) In an embodiment of the present invention, the method includes the process (17), and the heat treatment in the planarization layer formation step is performed at 120 °C or higher and 350 °C or lower for 10 minutes or more and 90 minutes or less.

The present disclosure can provide a liquid crystal display panel having favorable transmittance and suppressed open-circuit defects, and a method for producing the liquid crystal display panel.

### BRIEF DESCRIPTION OF THE DRAWINGS

FIG. 1 is a schematic cross-sectional view of a liquid crystal display panel of Embodiment 1.

FIG. 2 is a schematic cross-sectional view of a first substrate in the liquid crystal display panel of Embodiment 1.

FIG. 3 is a scanning electron micrograph of a cross section of the first substrate in the liquid crystal display panel of Embodiment 1.

FIG. 4 is a schematic plan view of the first substrate in the liquid crystal display panel of Embodiment 1.

FIG. 5 is a schematic cross-sectional view of a first substrate in a liquid crystal display panel of Embodiment 2.

FIG. 6 is a schematic cross-sectional view of a first substrate in a liquid crystal display panel of Embodiment 3.

FIG. 7 is a schematic cross-sectional view of a COA substrate of a comparative embodiment.

### DETAILED DESCRIPTION

Hereinafter, embodiments of the present invention will be described. The present invention is not limited to the following embodiments, and various modifications may be made as appropriate within the scope of the configuration of the present invention. In the following description, identical or functionally similar components are denoted by the same reference signs across different figures, and repeated descriptions thereof are omitted as appropriate. The embodiments of the present invention may be combined as appropriate without departing from the gist of the present invention.

### Embodiment 1

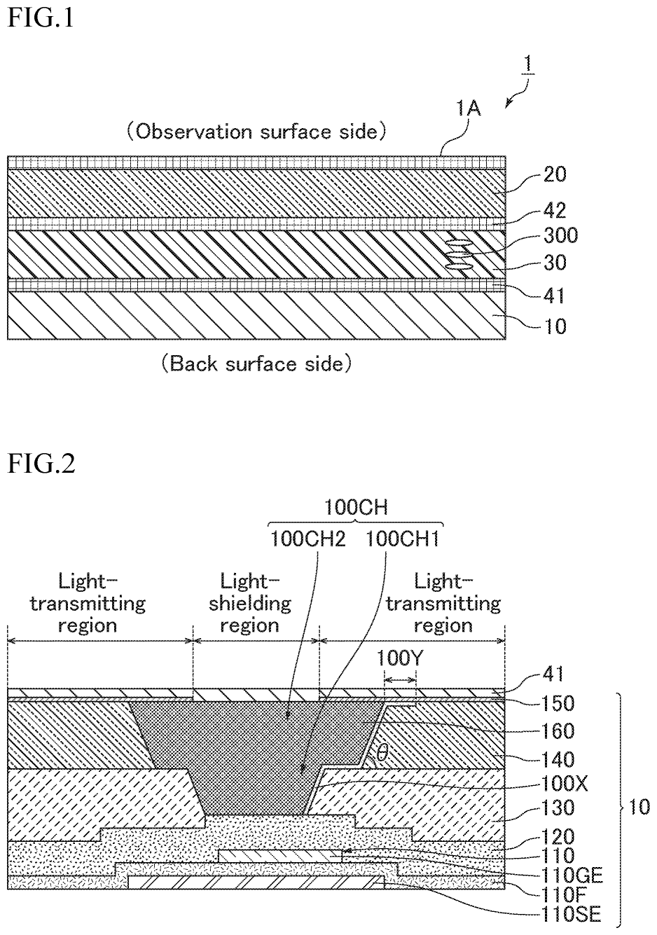

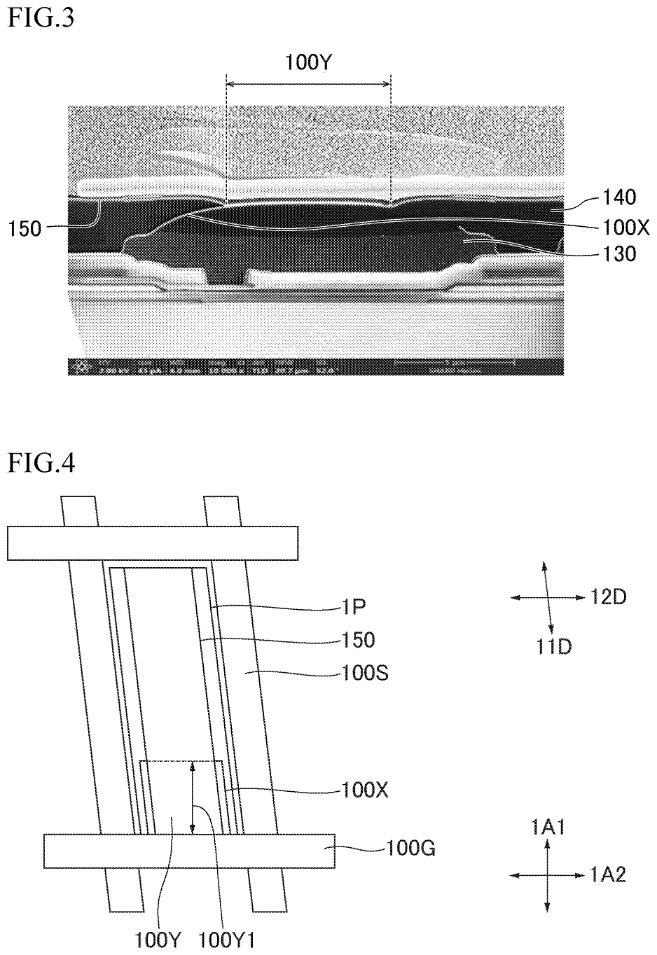

FIG. 1 is a schematic cross-sectional view of a liquid crystal display panel of Embodiment 1. FIG. 2 is a schematic cross-sectional view of a first substrate in the liquid crystal display panel of Embodiment 1. FIG. 3 is a scanning electron micrograph of a cross section of the first substrate in the liquid crystal display panel of Embodiment 1. FIG. 4 is a schematic plan view of the first substrate in the liquid crystal display panel of Embodiment 1.

As shown in FIG. 1 to FIG. 3, a liquid crystal display panel 1 of the present embodiment includes a first substrate 10, a second substrate 20 opposite to the first substrate 10, and a liquid crystal layer 30 sandwiched between the first substrate 10 and the second substrate 20. The first substrate 10 includes, sequentially toward the liquid crystal layer 30, thin film transistors (TFTs) 110 serving as switching elements, a color filter (CF) layer 130, a planarization layer 140 formed from a resist composition that contains a positive resist and a crosslinkable polymer having a crosslinkable group, and pixel electrodes 150. The first substrate 10 further includes connection electrodes 100X which connect the TFTs 110 and the respective pixel electrodes 150 via openings 100CH formed through the CF layer 130 and the planarization layer 140, and connection regions 100Y where the pixel electrodes 150 and the respective connection electrodes 100X are in contact with each other. In this configuration, a decrease in aperture ratio caused by misalignment during bonding between a pair of substrates (the first substrate 10 and the second substrate 20) constituting the liquid crystal display panel 1 can be suppressed, resulting in suppression of a decrease in transmittance of the liquid crystal display panel 1.

The planarization layer 140 has a taper angle θ of 30° or greater and 50° or less at the openings 100CH (hereinafter, the taper angle θ at the openings 100CH is also referred to simply as the taper angle θ of the planarization layer 140). A taper angle θ of the planarization layer 140 at the openings 100CH of 30° or greater can narrow the connection regions 100Y, increasing the transmittance of the liquid crystal display panel 1. Moreover, a decrease in voltage holding ratio after high-temperature aging can be suppressed. Meanwhile, a taper angle θ of the planarization layer 140 at the openings 100CH of 50° or less reduces the occurrence of open-circuit defects in the connection electrodes 100X. In particular, when paddle development is performed, in which a developer is dispensed onto the substrate during patterning of an organic film in the substrate production process, irregularities tend to occur on the film surface (for example, color filter layer). Forming electrodes on such irregularities may cause open-circuit defects. However, the open-circuit defects in the electrodes can be suppressed by setting the taper angle θ of the planarization layer 140 to 50° or less.

As shown in FIG. 4, an overlap length 100Y1, defined as a length from one end to the other end of the connection region 100Y in a vertical direction 1A1 of a screen 1A of the liquid crystal display panel 1 or in a horizontal direction 1A2 of the screen 1A, is 1 μm or greater and 3 μm or less. An overlap length 100Y1 of 1 μm or greater can further ensure the connection between the connection electrodes 100X and the pixel electrodes 150, suppressing open-circuit defects. An overlap length 100Y1 of 3 μm or less can narrow the connection regions 100Y, increasing the transmittance of the liquid crystal display panel 1.

In a head mounted display (HMD), an image displayed on a display panel is enlarged by a lens. This means that when the resolution of the display panel is low, a screen door effect may occur, in which boundaries between dots of the display panel become visible. Therefore, a display panel for HMD preferably has a resolution of 1000 ppi or more. For example, in a 1000-ppi display panel, the pixel size is about 25 μm or less, and the sub-pixel size is ⅓ of the pixel size, which is about 8 μm. The display panel (for example, liquid crystal display panel) is therefore required to have a high transmittance.

In a conventional liquid crystal display panel, misalignment may occur during bonding between a thin film transistor (TFT) substrate including TFTs and a color filter (CF) substrate including a CF layer, which may decrease the transmittance (reduce the light-transmitting region) of the liquid crystal display panel. One way of avoiding a decrease in transmittance is to use a color filter on array (COA) substrate in which a CF layer is disposed on an array (TFT) substrate.

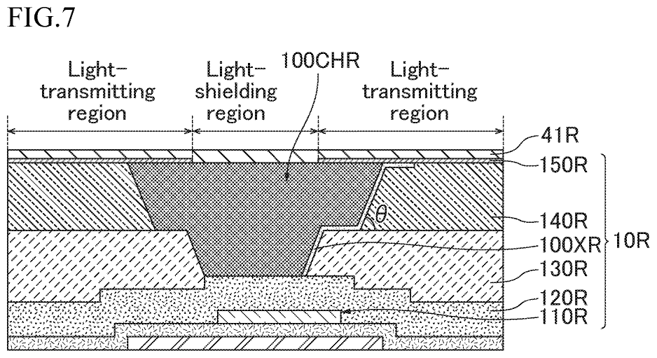

FIG. 7 is a schematic cross-sectional view of a COA substrate of a comparative embodiment. As shown in FIG. 7, a COA substrate 10R of a comparative embodiment includes an insulating layer 120R, a CF layer 130R, a planarization layer 140R, and pixel electrodes 150R in this order on TFTs 110R. To connect the TFTs 110R and the respective pixel electrodes 150R, the COA substrate 10R further includes connection electrodes 100XR which connect the TFTs 110R and the respective pixel electrodes 150R via openings 100CHR formed through the CF layer 130R and the planarization layer 140R. An alignment film 41R (for example, photoalignment film) is disposed on the pixel electrodes 150R of the COA substrate 10R. Use of the COA substrate 10R of the comparative embodiment having such a structure can suppress a decrease in transmittance of the liquid crystal display panel. However, when a COA substrate is employed for a high-resolution liquid crystal display panel, the light-transmitting area of the COA substrate tends to be insufficiently large, which in turn results in a low transmittance of the COA substrate.

One cause of the low transmittance of the COA substrate is presumably the low transmittance of the planarization layer 140R (in particular, the transmittance of the blue wavelength region). This issue can be addressed by increasing the transmittance of the planarization layer 140R. However, when the transmittance of the planarization layer 140R is increased, the planarization layer 140R and the CF layer 130R may be degraded due to alignment exposure (polarized ultraviolet (UV) light irradiation) performed on the photoalignment film. Another cause of the decrease in transmittance of the COA substrate is presumably the low transmittance caused by electrodes in regions in which a connection electrode 100XR and a corresponding pixel electrode 150R are present or overlap.

The following provides detailed descriptions of the liquid crystal display panel 1 of the present embodiment.

As shown in FIG. 1, the liquid crystal display panel 1 of the present embodiment sequentially includes the first substrate 10, the liquid crystal layer 30, and the second substrate 20. In the present embodiment, the first substrate 10 is disposed on the back surface side, while the second substrate 20 is disposed on the observation surface side. However, the first substrate 10 may instead be disposed on the observation surface side, and the second substrate 20 may be disposed on the back surface side.

The liquid crystal display panel 1 preferably includes a first alignment film 41 between the first substrate 10 and the liquid crystal layer 30. The liquid crystal display panel 1 preferably includes a second alignment film 42 between the second substrate 20 and the liquid crystal layer 30.

The liquid crystal display panel 1 preferably includes a first polarizing plate disposed on the side of the first substrate 10 opposite to the liquid crystal layer 30 and having a first polarization axis, and a second polarizing plate disposed on the side of the second substrate 20 opposite to the liquid crystal layer 30 and having a second polarization axis perpendicular to the first polarization axis. The liquid crystal display panel 1 may further include a backlight on the side of the first polarizing plate opposite to the liquid crystal layer 30.

Herein, unless otherwise specified, two straight lines (including polarization axes and directions) are regarded as perpendicular when an angle between them is 87° or greater and 90° or less, preferably 89° or greater and 90° or less, more preferably 89.5° or greater and 90° or less, particularly preferably 90° (perfectly perpendicular). Herein, two straight lines (including polarization axes and directions) are regarded as parallel when an angle (absolute value) between them is 0° or greater and 3° or less, preferably 0° or greater and 1° or less, more preferably 0° or greater and 0.5° or less, particularly preferably 0° (perfectly parallel).

As shown in FIG. 1 to FIG. 4, the liquid crystal display panel 1 has an active area (image display region) where images are displayed. The active area is defined by a plurality of sub-pixels 1P arranged in a matrix pattern in a vertical direction (up-down direction) 1A1 of the screen 1A and in a horizontal direction (left-right direction) 1A2 of the screen 1A. The vertical direction 1A1 of the screen 1A corresponds to a column direction of the sub-pixels 1P arranged in a matrix pattern (hereinafter, also referred to simply as “column direction”). The horizontal direction 1A2 of the screen 1A corresponds to a row direction of the sub-pixels 1P arranged in a matrix pattern (hereinafter, also referred to simply as “row direction”).

The first substrate 10 includes a first support substrate; a plurality of source lines 100S disposed on the side of the first support substrate facing the liquid crystal layer 30 and extending parallel to one another in a first direction 11D; and a plurality of gate lines 100G disposed on the side of the plurality of source lines 100S facing the liquid crystal layer 30 via an insulating layer and extending parallel to one another in a second direction 12D which intersects the first direction 11D. The plurality of gate lines 100G and the plurality of source lines 100S are formed in an overall grid pattern, partitioning the individual sub-pixels 1P. The TFTs 110 are each disposed at an intersection between a gate line 100G and a source line 100S.

The first direction 11D in the present embodiment is tilted relative to the column direction. The second direction 12D in the present embodiment is parallel to the row direction. The angle between the first direction 11D and the second direction 12D is preferably 70° or greater and 95° or less, preferably 75° or greater and 92° or less, more preferably 80° or greater and 90° or less. In such a configuration, the aperture ratio of the sub-pixels 1P can be improved. Although the second direction 12D corresponds to the row direction in the present embodiment, the first direction 11D may correspond to the row direction.

In the present embodiment, the source lines 100S have a zigzag shape that bends near gate electrodes 110GE of TFTs 110 so as to align the tilt directions of the pixel electrodes 150. In the present embodiment, when a focus is placed on a portion of each source line 100S, the source lines 100S appear to extend in a direction (first direction 11D) tilted relative to the column direction (vertical direction 1A1) as shown in FIG. 4. However, as a whole, the source lines 100S extend in the column direction. In other words, the direction from one end to the other end of each source line 100S in its longitudinal direction lies along the column direction.

In the present embodiment, the first direction 11D is tilted relative to the column direction. However, the first direction 11D may not be tilted relative to the column direction. For example, the first direction 11D may be parallel to the column direction. In this case, the first direction 11D is perpendicular to the second direction 12D.

As shown in FIG. 2, the first substrate 10 includes, sequentially toward the liquid crystal layer 30, the TFTs 110, an insulating layer 120, the CF layer 130, the planarization layer 140, and the pixel electrodes 150. The first substrate 10 further includes the connection electrodes 100X which connect the TFTs 110 and the pixel electrodes 150 via the openings 100CH formed through the CF layer 130 and the planarization layer 140, and the connection regions 100Y in which the pixel electrodes 150 and the connection electrodes 100X are in contact with each other.

The TFTs 110 are three-terminal switches, each connected to a corresponding one of the plurality of gate lines 100G and a corresponding one of the plurality of source lines 100S. Each TFT 110 includes a gate electrode 110GE extending from the corresponding gate line 100S (or constituting part of the gate line 100G), a source electrode extending from the corresponding source line 100S (or constituting part of the source line 100S), a drain electrode connected to a corresponding one of the plurality of pixel electrodes 150, and a semiconductor layer 110SE. A gate insulating layer 110F is disposed between the gate electrode 110GE and the semiconductor layer 110SE.

The source electrodes and the drain electrodes are formed in the same source line layer as the source lines 100S. The gate electrodes 110GE are formed in the same gate line layer as the gate lines 100G. Each semiconductor layer 110SE is connected to a corresponding drain electrode via a through hole. Each pixel electrode 150 is connected to a corresponding drain electrode via a corresponding opening 100CH.

The liquid crystal display panel 1 includes a gate driver connected to the gate lines 100G, a source driver connected to the source lines 100S, and a controller connected to the gate driver and the source driver. The gate driver sequentially supplies scanning signals to the gate lines 100G under control by the controller. The source driver, under control by the controller, supplies a data signal to a source line 100S when a corresponding TFT 110 is turned into a voltage-applied state by a scanning signal.

Each pixel electrode 150 is set to an electrical potential corresponding to the data signal supplied via the corresponding TFT 110. This generates an electric field between the common electrode and the pixel electrode 150, thereby rotating liquid crystal molecules 300 in the liquid crystal layer 30. In this manner, the magnitude of the voltage applied between the common electrode and each pixel electrode 150 is controlled to vary the retardation in the liquid crystal layer 30, thereby controlling the transmission and blocking of light.

The gate lines 100G, the source lines 100S, and the conductive lines and electrodes that constitute the TFTs 110 can be formed by depositing a single-layer or multilayer film of a metal such as copper, titanium, aluminum, molybdenum, or tungsten, or an alloy thereof by sputtering or another method, and then patterning the film by photolithography or another method. These conductive lines and electrodes that are formed in the same layer can be efficiently produced by using the same material.

The semiconductor layers 110SE preferably include an oxide semiconductor or polycrystalline silicon (p-Si). The oxide semiconductor may be, for example, indium-gallium-zinc oxide (In—Ga—Zn—O; IGZO®) or zinc oxide (ZnO), but is not limited thereto.

The gate insulating layers 110F are, for example, inorganic insulating films. Examples of the inorganic insulating films include inorganic films (dielectric constant ¿=5 to 7) such as silicon nitride (SiNₓ) and silicon oxide (SiO₂) films, and laminate films thereof.

The insulating layer 120 is an inorganic insulating film, an organic insulating film, or a laminate of the organic insulating film and the inorganic insulating film. The inorganic insulating film may be, for example, an inorganic film (dielectric constant ¿=5 to 7) such as a silicon nitride (SiNₓ) or silicon oxide (SiO₂) film, or a laminate film thereof. The organic insulating film may be, for example, a low-dielectric-constant organic film (dielectric constant ε=2 to 5) such as a photosensitive acrylic resin film or a laminate film thereof.

The CF layer 130 is disposed on the side of the insulating layer 120 facing the liquid crystal layer 30. The CF layer 130 includes, for example, red color filters, blue color filters, and green color filters. The red color filters, the blue color filters, and the green color filters are mainly formed from, for example, negative-type resist materials and pigments of the corresponding colors. The negative-type resist materials preferably include a photopolymerization initiator, an acrylic-based monomer, and an imide-based polymer.

The CF layer 130 preferably includes an antioxidant. The antioxidant may be, for example, a phenol-based antioxidant, a phosphorus-based antioxidant, or a sulfur-based antioxidant. Specific examples include 6,6′-di-tert-butyl-4,4′-butylidenedi-m-cresol represented by the following chemical formula (AX1), tris(2,4-ditert-butylphenyl) phosphite represented by the following chemical formula (AX2), and di(tridecyl) 3,3′-thiodipropionate represented by the following chemical formula (AX3).

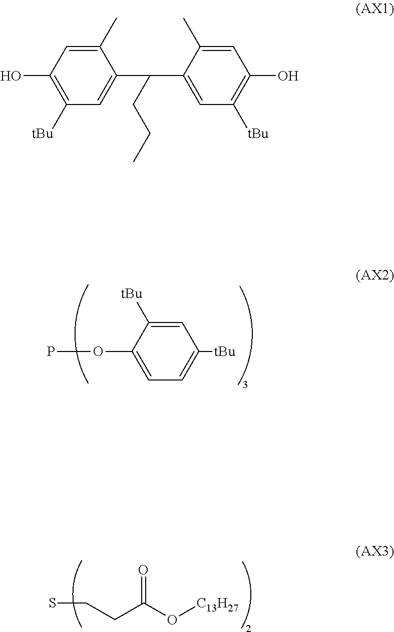

The plurality of sub-pixels 1P include, for example, red sub-pixels including red color filters, blue sub-pixels including blue color filters, and green sub-pixels including green color filters. One pixel is defined by three sub-pixels 1P, namely a red sub-pixel, a blue sub-pixel, and a green sub-pixel. The three sub-pixels 1P within one pixel are arranged in a stripe pattern. The CF layer 130 is, for example, a micro color filter layer.

The CF layer 130 preferably has a taper angle θ_{CF} of 30° or greater and 50° or less at the openings 100CH (the taper angle θ_{CF} at the openings 100CH is also referred to simply as the taper angle θ_{CF} of the CF layer 130). A taper angle θ_{CF} of the CF layer 130 at the openings 100CH of 30° or greater can further narrow the connection regions 100Y, further increasing the transmittance of the liquid crystal display panel 1. Meanwhile, a taper angle θ_{CF} of the CF layer 130 at the openings 100CH of 50° or less further reduces the occurrence of open-circuit defects in the connection electrodes 100X. The taper angle θ_{CF} is more preferably 35° or greater and 50° or less, particularly preferably 40° or greater and 50° or less.

The taper angle θ_{CF} of the CF layer 130 can be set, for example, according to the type of developer, the developing time, the baking temperature, and the baking time.

The planarization layer 140 is disposed on the side of the CF layer 130 facing the liquid crystal layer 30. The planarization layer 140 is an insulating film that absorbs irregularities of its underlying surface (underlayer) on which the planarization layer 140 is formed and planarizes the substrate surface where the planarization layer 140 is formed. The planarization layer 140 can maintain a uniform cell thickness of the liquid crystal display panel 1.

The planarization layer 140 is formed from a resist composition that contains a positive resist and a crosslinkable polymer having a crosslinkable group. In this configuration, the amount of the positive resist contained in the planarization layer 140 can be reduced, and thus the transmittance of the planarization layer 140 can be increased. When the amount of the positive resist contained in the resist composition is taken as 100 parts by mass, the amount of the crosslinkable polymer having a crosslinkable group is preferably 3 parts by mass or greater and 70 parts by mass or less, more preferably 5 parts by mass or greater and 60 parts by mass or less. In this configuration, the planarization layer 140 can be formed without insufficient development, i.e., without leaving residues, and without removing the planarization layer 140 in regions where it is required. The planarization layer 140 can be obtained by subjecting the resist composition to an exposure treatment and a development treatment, followed by a heat treatment.

The positive resist is preferably at least one compound selected from the group consisting of naphthoquinone diazide and naphthoquinone diazide derivatives. This configuration enables the planarization layer 140 to be formed in a short reaction time without leaving any residue, thereby improving production throughput. The naphthoquinone diazide and naphthoquinone diazide derivatives may also be referred to collectively as compounds having a naphthoquinone diazide group.

The positive resist preferably has a structure represented by the following chemical formula (PLN1). This configuration enables the planarization layer 140 to be formed in a short reaction time without leaving any residue, thereby improving production throughput.

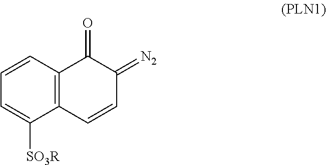

In the formula, R represents Cl or Br.

The crosslinkable group in the crosslinkable polymer is preferably at least one crosslinkable group selected from the group consisting of epoxy groups and isocyanate groups. This configuration enables crosslinking in a short reaction time, thereby improving production throughput.

The crosslinkable polymer is preferably an imide-based polymer. This configuration enables crosslinking in an even shorter reaction time, thereby improving production throughput. The polymer having a crosslinkable group preferably has a structure represented by the following chemical formula (PLN2). This configuration enables the planarization layer 140 to exhibit high thermal stability.

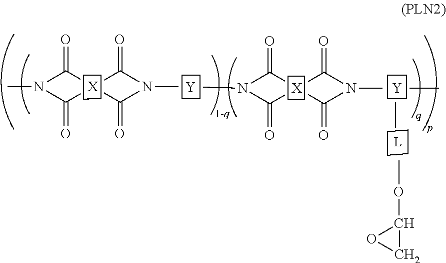

In the formula, X is a tetravalent organic group, Y is a divalent organic group, L is an alkylene group, p is an integer of 10 or greater, q represents a mass fraction of a structural unit in the main chain and is a real number of 0.02 or greater and less than 0.2.

In the chemical formula (PLN2), X is a tetravalent organic group. X is preferably a C4-C24 tetravalent organic group. This configuration enables the planarization layer 140 to exhibit high thermal stability.

X is preferably a group represented by the following chemical formula (X-1). This configuration enables the planarization layer 140 to exhibit sufficiently high thermal stability.

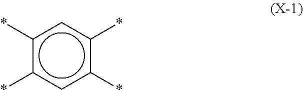

In the formula, * represents a bonding site.

In the chemical formula (PLN2), Y is a divalent organic group. Y is preferably a C2-C24 divalent organic group. This configuration enables the planarization layer 140 to maintain high thermal stability while retaining its elasticity.

Y is preferably a group represented by the following chemical formula (Y-1) or (Y-2). This configuration enables the planarization layer 140 to maintain high thermal stability while retaining its elasticity.

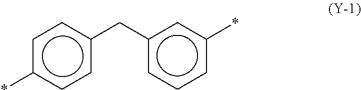

In the formula, * represents a bonding site.

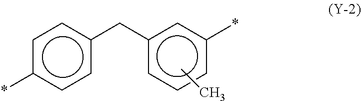

In the formula, * represents a bonding site.

In the chemical formula (PLN2), L is an alkylene group. The alkylene group may have a linear structure or a branched structure. Lis preferably a C2-C24 alkylene group. This configuration enables the crosslinking reaction to readily occur. L may be, for example, a methylene, ethylene, propylene, butylene, or cyclophenylene group.

In the chemical formula (PLN2), p is an integer of 10 or greater. The upper limit of p is not limited, and p is, for example, an integer of 1000 or less.

In the chemical formula (PLN2), q represents a mass fraction of a structural unit in the main chain, and is a real number of 0.02 or greater and less than 0.2. This configuration can achieve the desired taper angle and a sufficiently high crosslinking density. q is preferably a real number of 0.05 or greater and less than 0.2, more preferably a real number of 0.10 or greater and less than 0.2.

The resist composition preferably further contains a hydroxy compound. This configuration can facilitate the crosslinking reaction with the epoxy compound. When the amount of the positive resist contained in the resist composition is defined as 100 parts by mass, the amount of the hydroxy compound is preferably 10 parts by mass or greater and 70 parts by mass or less, more preferably 20 parts by mass or greater and 60 parts by mass or less. This configuration can effectively facilitate the crosslinking reaction with the epoxy compound. The hydroxy compound is preferably a novolac resin. This configuration can achieve an even higher degree of crosslinking.

The hydroxy compound preferably has a structure represented by the following chemical formula (PLN3). This configuration can maintain the high film elasticity of the planarization layer 140.

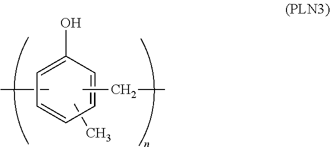

In the formula, n represents an integer of 15 or greater.

When mixed with each other, the positive resist and the hydroxy compound define a compound having a structure represented by the following chemical formula (PLN11). Compounds having structures represented by the chemical formula (PLN11) are insoluble in a developer.

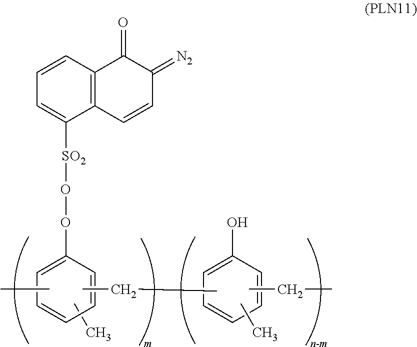

In the formula, m represents an integer of 5 or greater, and n represents an integer of 10 or greater.

When irradiated with ultraviolet light, compounds having structures represented by the chemical formula (PLN11) are converted into compounds having structures represented by the following chemical formula (PLN12). Compounds having structures represented by the chemical formula (PLN12) are soluble in a developer.

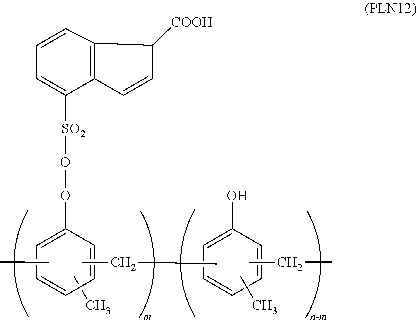

In the formula, m represents an integer of 5 or greater, and n represents an integer of 10 or greater.

The planarization layer 140 has a taper angle θ of 30° or greater and 50° or less at the openings 100CH. This configuration can increase the transmittance of the liquid crystal display panel 1 and reduce open-circuit defects in the connection electrodes 100X. The taper angle θ is preferably 35° or greater and 50° or less, still more preferably 40° or greater and 50° or less.

The taper angle θ of the planarization layer 140 can be set to a desired angle, for example, by adjusting the temperature and time of a heat treatment (post-bake) performed after applying the resist composition to the CF layer 130, pre-baking the resist composition, and forming a pattern by ultraviolet light exposure and development treatments. The taper angle θ of the planarization layer 140 can also be varied depending on the type and amount of the crosslinkable polymer and the combination with the material(s) constituting the underlayer of the planarization layer 140.

The post-bake temperature is preferably 120 °C or higher and 350 °C or lower. This configuration facilitates adjustment of the taper angle θ to a range of 30° or greater and 50° or less. The post-bake temperature is more preferably 160 °C or higher and 230 °C or lower, still more preferably 180 °C or higher and 220 °C or lower.

The post-bake time is preferably 10 minutes or more and 90 minutes or less. This configuration facilitates adjustment of the taper angle θ to a range of 30° or greater and 50° or less. The post-bake time is more preferably 10 minutes or more and 60 minutes or less, still more preferably 10 minutes or more and 40 minutes or less.

The planarization layer 140 preferably has a molecular weight distribution (Mw/Mn) of 10 or greater and 20 or less. When the planarization layer 140 has a molecular weight distribution of 10 or greater, the taper angle θ can be easily set to 50° or less. When the planarization layer 140 has a molecular weight distribution of 20 or less, the taper angle θ can be easily set to 30° or greater.

The molecular weight distribution refers to a value (Mw/Mn) obtained by dividing the weight-average molecular weight Mw by the number-average molecular weight Mn, wherein both Mw and Mn are measured by gel permeation chromatography (GPC). Mw and Mn can be determined, for example, by dissolving the planarization layer in tetrahydrofuran (THF) to a concentration of 20% by weight to prepare a specimen, and injecting 10 μL of the specimen into a GPC system (available from Tosoh Corporation, model: HLC-8220GPC) set to a column temperature of 40 °C.

The molecular weight distribution of the planarization layer 140 can be set to a desired value, for example, by adjusting the temperature and time of the post-bake performed after applying the resist composition to the CF layer 130, pre-baking the resist composition, and forming a pattern by ultraviolet light exposure and development treatments. The molecular weight distribution of the planarization layer 140 can also be varied depending on the type and amount of the crosslinkable polymer and the combination with the material(s) constituting the underlayer of the planarization layer 140.

The post-bake temperature is preferably 120 °C or higher and 350 °C or lower. This configuration facilitates adjustment of the molecular weight distribution of the planarization layer 140 to a range of 10 or greater and 20 or less. The post-bake temperature is more preferably 160 °C or higher and 230 °C or lower, still more preferably 180 °C or higher and 220 °C or lower.

The post-bake time is preferably 10 minutes or more and 90 minutes or less. This configuration facilitates adjustment of the molecular weight distribution of the planarization layer 140 to a range of 10 or greater and 20 or less. The post-bake time is more preferably 10 minutes or more and 60 minutes or less, still more preferably 10 minutes or more and 40 minutes or less.

The planarization layer 140 preferably includes an antioxidant. The antioxidant may be, for example, a phenol-based antioxidant, a phosphorus-based antioxidant, or a sulfur-based antioxidant. Specific examples thereof include 6,6′-di-tert-butyl-4,4′-butylidenedi-m-cresol represented by the chemical formula (AX1), tris(2,4-ditert-butylphenyl) phosphite represented by the chemical formula (AX2), and di(tridecyl) 3,3′-thiodipropionate represented by the chemical formula (AX3).

The CF layer 130 and the planarization layer 140 preferably differ in polarity. This configuration can effectively suppress open-circuit defects in the liquid crystal display panel 1.

Each pixel electrode 150 is disposed in a corresponding region surrounded by two adjacent gate lines 100G and two adjacent source lines 100S. Each pixel electrode is disposed in a corresponding sub-pixel 1P. Each pixel electrode 150 is connected to a corresponding TFT 110 and to a corresponding source line 100S via the semiconductor layer 110SE of the TFT 110. Each pixel electrode 150 is set to an electrical potential corresponding to the data signal supplied via the corresponding TFT 110.

The liquid crystal display panel 1 further includes a common electrode. The common electrode may be disposed in the first substrate 10 or in the second substrate 20.

A liquid crystal display panel 1 in which the common electrode is disposed in the first substrate 10 is a transverse electric-field-mode liquid crystal display panel that displays images by applying a voltage between the pixel electrodes 150 and the common electrode to generate transverse electric fields (including fringe electric fields) in the liquid crystal layer 30. Examples of transverse electric-field-mode liquid crystal display panels include fringe field switching (FFS) mode liquid crystal display panels and in plane switching (IPS) mode liquid crystal display panels in which the liquid crystal molecules in the liquid crystal layer 30 are aligned parallel to the substrate surfaces when no voltage is applied. The common electrode may be disposed, via an insulating film, either on the side of the pixel electrodes 150 facing the liquid crystal layer 30 or on the side of the pixel electrodes 150 opposite to the liquid crystal layer 30.

A liquid crystal display panel 1 in which the common electrode is disposed in the second substrate 20 is a vertical electric-field-mode liquid crystal display panel that displays images by applying a voltage between the pixel electrodes 150 and the common electrode to generate vertical electric fields in the liquid crystal layer 30. Examples of vertical electric-field-mode liquid crystal display panels include vertical alignment (VA) mode liquid crystal display panels in which the liquid crystal molecules in the liquid crystal layer 30 are aligned perpendicular to the substrate surfaces when no voltage is applied.

The common electrode is, for example, an electrode formed over substantially the entire surface, irrespective of the boundaries between the sub-pixels 1P. A common signal that is maintained at a constant value is supplied to the common electrode, which maintains the common electrode at a constant electrical potential.

Each connection electrode 100X connects a TFT 110 and a corresponding pixel electrode 150 via a corresponding opening 100CH formed through the CF layer 130 and the planarization layer 140.

The pixel electrodes 150, the common electrode, and the connection electrodes 100X are formed, for example, by depositing a single-layer or multilayer film of a transparent conductive material such as indium tin oxide (ITO), indium zinc oxide (IZO), zinc oxide (ZnO), tin oxide (SnO), or indium-gallium-zinc oxide (IGZO®) or an alloy thereof by sputtering or another method, and then patterning the film by photolithography. The pixel electrodes 150, the common electrode, and the connection electrodes 100X have a thickness of, for example, 30 nm or greater and 100 nm or less.

Each connection region 100Y is a region in which a pixel electrode 150 and a corresponding connection electrode 100X are in contact with each other. The overlap length 100Y1, defined as a length from one end to the other end of the connection region 100Y in the vertical direction 1A1 of the screen 1A of the liquid crystal display panel 1 or in the horizontal direction 1A2 of the screen 1A, is 1 μm or greater and 3 μm or less. This configuration can reduce the overlap between the pixel electrode 150 and the connection electrode 100X while maintaining the contact between them. This can further ensure the connection between the connection electrode 100X and the pixel electrode 150, thereby suppressing open-circuit defects, while increasing the transmittance of the liquid crystal display panel 1. The screen 1A of the liquid crystal display panel 1 has, for example, a rectangular shape.

The liquid crystal display panel 1 may include an opening insulating layer 160 disposed in each opening 100CH. The opening insulating layer 160 is an inorganic insulating film, an organic insulating film, or a laminate of an organic insulating film and an inorganic insulating film. The inorganic insulating film may be, for example, an inorganic film (dielectric constant ε=5 to 7) such as a silicon nitride (SiNₓ) or silicon oxide (SiO₂) film, or a laminate film thereof. The organic insulating film may be, for example, an organic film having a low dielectric constant (dielectric constant ε=2 to 5) such as a photosensitive acrylic resin film, or a laminate film thereof.

The liquid crystal layer 30 contains a liquid crystal material. A voltage is applied to the liquid crystal layer 30 to change the alignment of the liquid crystal molecules 300 in the liquid crystal material according to the applied voltage, thereby controlling the amount of transmitted light. The liquid crystal material exhibits nematic liquid crystallinity within a specific temperature range.

The liquid crystal molecules 300 are horizontally aligned or vertically aligned when no voltage is applied.

The state where the liquid crystal molecules 300 are horizontally aligned means that when no voltage is applied to the liquid crystal layer 30, the liquid crystal molecules 300 in the liquid crystal layer 30 are aligned substantially parallel to the main surfaces of the first substrate 10 and the second substrate 20. Here, the state where the liquid crystal molecules are aligned substantially parallel to the main surfaces of the substrates means that the pre-tilt angle of the liquid crystal molecules is 0° or greater and 5° or less, preferably 0° or greater and 2° or less, more preferably 0° or greater and 1° or less, relative to the main surfaces of the substrates.

The state where the liquid crystal molecules 300 are vertically aligned means that, when no voltage is applied to the liquid crystal layer 30, the liquid crystal molecules 300 in the liquid crystal layer 30 are aligned substantially perpendicular to the main surfaces of the first substrate 10 and the second substrate 20. Here, the state where the liquid crystal molecules are aligned substantially perpendicular to the main surfaces of the substrates means that the pre-tilt angle of the liquid crystal molecules is 85° or greater and 90° or less, preferably 88° or greater and 90° or less, more preferably 89° or greater and 90° or less, relative to the main surfaces of the substrates.

Herein, a voltage application state where a voltage equal to or greater than the threshold is applied between a pixel electrode and a common electrode is also simply referred to as a “voltage applied state” or “during voltage application”. A no voltage application state where a voltage less than the threshold is applied between a pixel electrode and the common electrode (including no voltage application) is also simply referred to as a “no-voltage applied state” or “during no voltage application”.

Liquid crystal molecules having a positive anisotropy of dielectric constant (Δε), as defined by the following formula (L1), are referred to also as positive liquid crystals. Liquid crystal molecules having a negative anisotropy of dielectric constant are referred to also as negative liquid crystals. The long axis direction of the liquid crystal molecules 300 is defined as an alignment direction (slow axis direction). The liquid crystal molecules 300 are homogenously aligned in a state where no voltage is applied between a pixel electrode and the common electrode (no voltage applied state).

Δε=(dielectric constant in long axis direction of liquid crystal molecules)−(dielectric constant in short axis direction of liquid crystal molecules) Formula (L1)

The liquid crystal molecules 300 in the present embodiment preferably have a positive anisotropy of dielectric constant. The liquid crystal display panel 1 having such a configuration can improve the response time.

The first alignment film 41 and the second alignment film 42 (hereinafter, referred to also simply as alignment films) function to control the alignment of the liquid crystal molecules 300 in the liquid crystal layer 30. When the voltage applied to the liquid crystal layer 30 is less than the threshold voltage (including no voltage application), the alignment of the liquid crystal molecules 300 in the liquid crystal layer 30 is controlled mainly by the alignment films. The material of the alignment films can be a material typically used in the field of liquid crystal display panels, such as a polymer having a polyimide structure in the main chain, a polymer having a polyamic acid structure in the main chain, or a polymer having a polysiloxane structure in the main chain.

The alignment films can be formed by applying an alignment-film material using a non-limiting application method such as flexographic printing or ink-jet application.

The alignment films may be horizontal alignment films which align the liquid crystal molecules 300 substantially parallel to the film surfaces (main surfaces of the substrates), or may be vertical alignment films which align the liquid crystal molecules 300 substantially perpendicular to the film surfaces (main surfaces of the substrates). The horizontal alignment films function to align the liquid crystal molecules 300 in the liquid crystal layer 30 parallel to the film surfaces (main surfaces of the substrates) in the pixel region when no voltage is applied to the liquid crystal layer 30 (when the voltage applied to the liquid crystal layer is less than the threshold voltage). The vertical alignment films function to align the liquid crystal molecules 300 in the liquid crystal layer 30 perpendicular to the film surfaces (main surfaces of the substrates) in the pixel region when no voltage is applied to the liquid crystal layer 30.

The alignment films are photoalignment films or rubbing alignment films. The alignment films are preferably photoalignment films. The photoalignment films are alignment films that include a photo-functional group and have been subjected to a photoalignment treatment as the alignment treatment. The rubbing alignment films are alignment films that have been subjected to a rubbing treatment as the alignment treatment.

The first alignment film 41 is a photoalignment film. The photoalignment film preferably includes a photoalignment film polymer having at least one functional group selected from the group consisting of photodegradable functional groups, photodimerizable functional groups, and photoisomerizable functional groups. When the first alignment film disposed on the side of the planarization layer facing the liquid crystal layer is a photoalignment film, the photoalignment treatment performed to form the photoalignment film exposes the planarization layer to ultraviolet light. As a result, the planarization layer degrades, possibly decreasing the transmittance of the liquid crystal display panel. However, the liquid crystal display panel 1 of the present embodiment can suppress a decrease in transmittance.

Examples of the photodegradable functional groups include cyclobutane groups and dimethyl cyclobutane groups. Examples of the photodimerizable functional groups include cinnamate groups, chalcone groups, and coumarin groups. Examples of the photoisomerizable functional groups include azobenzene groups.

The photoalignment film polymer preferably includes at least one group selected from the group consisting of cyclobutane, azobenzene, cinnamate, and coumarin groups. This configuration enables stable alignment treatment using polarized ultraviolet irradiation.

The photoalignment film polymer is preferably a polyimide having at least one group selected from the group consisting of cyclobutane, azobenzene, cinnamate, and coumarin groups. This configuration enables liquid crystal alignability with high thermal stability.

The first alignment film 41 may contain a base polymer in addition to the polyimide having at least one group selected from the group consisting of cyclobutane, azobenzene, cinnamate, and coumarin groups. The base polymer may be, for example, a polyimide or polyamic acid that does not have a photoreactive group.

The second substrate 20 may include a light-shielding layer (for example, black matrix layer) in regions corresponding to the TFTs 110, the gate lines 100G, and the source lines 100S.

Hereinafter, a method for producing the liquid crystal display panel 1 will be described.

The method for producing the liquid crystal display panel 1 of the present embodiment is a method for producing the liquid crystal display panel 1 which includes the first substrate 10 including the TFTs 110 serving as switching elements, the second substrate 20 facing the first substrate 10, and the liquid crystal layer 30 sandwiched between the first substrate 10 and the second substrate 20.

The method for producing the liquid crystal display panel 1 includes: a color filter layer formation step including forming a CF layer 130 provided with first openings 100CH1 above the TFTs 110 serving as switching elements; a planarization layer formation step including applying a resist composition that contains a positive resist and a crosslinkable polymer having a crosslinkable group to the side of the CF layer 130 opposite to the TFTs 110, performing an exposure treatment and a development treatment, and then performing a heat treatment, thereby forming the planarization layer 140 provided with the second openings 100CH2 overlapping the respective first openings 100CH1 in a plan view; a connection electrode formation step including forming the connection electrodes 100X that extend from the TFTs 110 to the surface of the planarization layer 140 opposite to the CF layer 130 through the openings 100CH defined by the first openings 100CH1 and the second openings 100CH2; and a pixel electrode formation step including forming the pixel electrodes 150 that are in contact with the respective connection electrodes 100X, on the side of the connection electrodes 100X opposite to the planarization layer 140.

The planarization layer 140 has a taper angle θ of 30° or greater and 50° or less at the openings 100CH. The overlap length 100Y1 is 1 μm or greater and 3 μm or less, the overlap length 100Y1 being defined as a length, measured in the vertical direction 1A1 of the screen 1A of the liquid crystal display panel 1 or in the horizontal direction 1A2 of the screen 1A, from one end to the other end of each connection region 100Y in which the connection electrode 100X and the corresponding pixel electrode 150 are in contact with each other.

This configuration can achieve a liquid crystal display panel 1 in which a decrease in transmittance is suppressed and open-circuit defects in the electrodes are suppressed.

In the color filter layer formation step, the CF layer 130 provided with the first openings 100CH1 is formed above the TFTs 110. In the color filter layer formation step, for example, red, green, and blue resist materials of color filters are sequentially formed by spin coating or slit coating, for example, and an exposure treatment and a development treatment are performed for patterning.

In the planarization layer formation step, a resist composition that contains a positive resist and a crosslinkable polymer having a crosslinkable group is applied to the side of the CF layer 130 opposite to the TFTs 110, an exposure treatment and a development treatment are performed, and then a heat treatment is performed, whereby the planarization layer 140 provided with the second openings 100CH2 overlapping the respective first openings 100CH1 in a plan view is formed. The heat treatment is referred to also as post-bake. The development treatment in the planarization layer formation step is preferably performed by paddle development. This configuration can further increase the transmittance of the liquid crystal display panel and further suppress open-circuit defects.

The heat treatment (post-bake) temperature is preferably 120 °C or higher and 350 °C or lower. This configuration facilitates adjustment of the taper angle θ to a range of 30° or greater and 50° or less. The post-bake temperature is more preferably 160 °C or higher and 230 °C or lower, still more preferably 180 °C or higher and 220 °C or lower.

The heat treatment (post-bake) time is preferably 10 minutes or more and 90 minutes or less. This configuration facilitates adjustment of the taper angle θ to a range of 30° or greater and 50° or less. The post-bake time is more preferably 10 minutes or more and 60 minutes or less, still more preferably 10 minutes or more and 40 minutes or less.

The heat treatment is more preferably performed at 120 °C or higher and 350 °C or lower for 10 minutes or more and 90 minutes or less. This configuration facilitates adjustment of the taper angle θ to a range of 30° or greater and 50° or less.

In the connection electrode formation step, the connection electrodes 100X are formed which extend from the respective TFTs 110 to the surface of the planarization layer 140 opposite to the CF layer 130 through the openings 100CH defined by the first openings 100CH1 and the second openings 100CH2. The connection electrodes 100X are formed by depositing a conductive film using a material of the connection electrodes 100X by sputtering or another method, and patterning the film into the desired shape.

In the pixel electrode formation step, the pixel electrodes 150 that are in contact with the corresponding connection electrodes 100X are formed on the side of the connection electrodes 100X opposite to the planarization layer 140. The pixel electrodes 150 are formed by depositing a conductive film using a material of the pixel electrodes 150 by sputtering or another method, and patterning the film into the desired shape.

### Embodiment 2

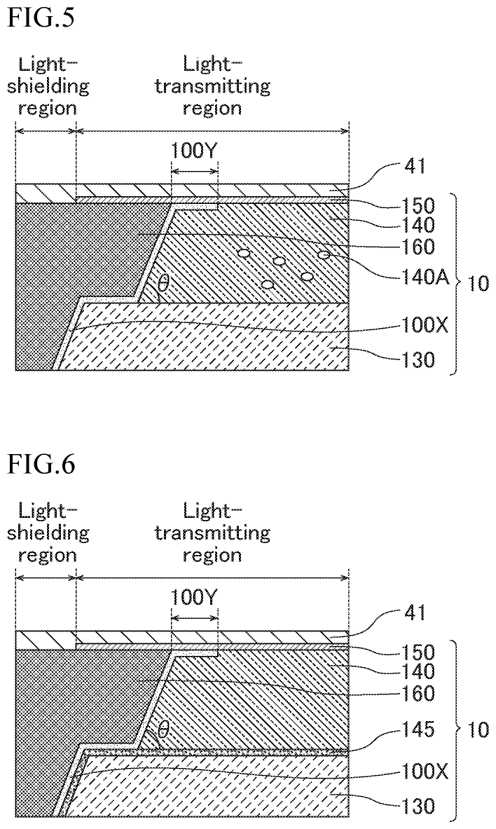

In the present embodiment, features unique to the present embodiment will mainly be described, and descriptions of matters identical to those in Embodiment 1 will be omitted. The present embodiment is substantially the same as Embodiment 1, except that the configuration of the planarization layer 140 is different. FIG. 5 is a schematic cross-sectional view of a first substrate in a liquid crystal display panel of Embodiment 2.

When the transmittance of the planarization layer 140 is increased, polarized ultraviolet light used in the photoalignment treatment performed on the first alignment film 41 may pass through the planarization layer 140 and reach the CF layer 130 positioned under the planarization layer 140, thereby degrading the CF layer 130 (specifically, the color materials of the CF layer 130). In addition, polarized ultraviolet light applied during the photoalignment treatment may generate radicals due to the positive resist contained in the planarization layer 140, thereby degrading the CF layer 130 (specifically, the color materials of the CF layer 130). Therefore, the planarization layer 140 may be made to absorb polarized ultraviolet light so as to suppress deterioration of the CF layer 130. However, in Embodiment 1, the amount of the positive resist, which absorbs ultraviolet to blue light, is preferably reduced to increase the transmittance and control the taper angle θ, which may result in insufficient absorption of polarized ultraviolet light by the planarization layer 140.

Meanwhile, the planarization layer 140 in the present embodiment contains a radical scavenger 140A having a radical-trapping group. The radical scavenger 140A becomes relatively stable by capturing radicals and is therefore capable of trapping radicals generated from other compounds, thereby enhancing light stability. Therefore, radicals generated in the planarization layer 140 upon irradiation with polarized ultraviolet light can be trapped by the radical scavenger 140A. As a result, degradation of the CF layer 130 can be suppressed.

The radical-trapping group may be any group that can trap radicals generated upon photoirradiation, particularly ultraviolet irradiation, and is preferably a nitroxyl radical group. This configuration enables an even higher rate of radical trapping.

The nitroxyl radical group is preferably a hindered amine group. This configuration enables an even higher rate of radical trapping. The radical scavenger 140A having a hindered amine group as a radical-trapping group is referred to also as a hindered amine light stabilizer (HALS).

The hindered amine group preferably has at least one structure selected from the group consisting of structures represented by the following chemical formula (A11) and structures represented by the following chemical formula (A12). Such a hindered amine group can become stable by capturing radicals, thereby achieving an even higher rate of radical trapping.

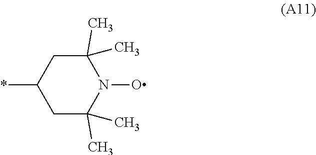

In the formula, * represents a bonding site.

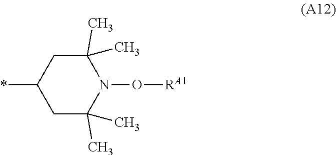

In the formula, R^{A1} represents a monovalent alkyl group, and * represents a bonding site.

In the chemical formula (A12), R^{A1} represents a monovalent alkyl group. The alkyl group may be linear, branched, or cyclic. R^{A1} preferably represents a C2-C20 monovalent alkyl group. This configuration can effectively trap radicals. Examples of R^{A1} include ethyl, propyl, and octadecyl groups.

The hindered amine group preferably has at least one structure selected from the group consisting of structures represented by the following chemical formula (A21) and structures represented by the following chemical formula (A22). A compound having such a hindered amine group can remain stable in a film and enables an even higher rate of radical trapping.

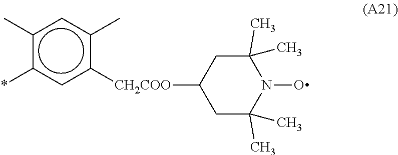

In the formula, * represents a bonding site.

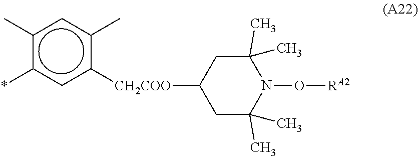

In the formula, R^{A2} represents a monovalent alkyl group, and * represents a bonding site.

In the chemical formula (A22), R^{A2} represents a monovalent alkyl group. The alkyl group nay be linear, branched, or cyclic. R^{A2} preferably represents a C2-C20 monovalent alkyl group. A compound having such a hindered amine group can remain stable in a film and enables an even higher rate of radical trapping. Examples of R^{A2} include ethyl, propyl, and octadecyl groups.

The radical-trapping group is also preferably a hydrazyl radical group. This configuration can achieve a significantly high rate of radical trapping.

The hydrazyl radical group preferably has a structure represented by the following chemical formula (B). A compound having such a hydrazyl radical group can remain stable in a film and enables a significantly high rate of radical trapping.

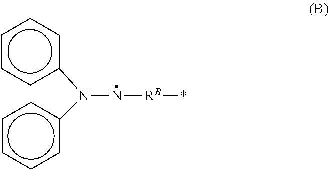

In the formula, R^{B} represents a divalent organic group, and * represents a bonding site.

In the chemical formula (B), R^{B} represents a divalent organic group. R^{B} is preferably a C2-C20 divalent organic group. A compound having such a hydrazyl radical group can remain stable in a film and enables a significantly high rate of radical trapping. Examples of R^{B} include ethyl, propyl, and octadecyl groups.

The amount of the radical scavenger 140A contained in the planarization layer 140 is preferably greater than 0 wt % and less than 16 wt %. This configuration can increase the transmittance of the planarization layer 140. As a result, the transmittance of the liquid crystal display panel 1 can be increased. The amount of the radical scavenger contained in the planarization layer is the total weight of the radical scavenger relative to the total weight of the planarization layer.

### Embodiment 3

In the present embodiment, features unique to the present embodiment will mainly be described, and descriptions of matters identical to those in Embodiments 1 and 2 will be omitted. The present embodiment is substantially the same as Embodiment 1, except that a radical-trapping layer is disposed between the CF layer 130 and the planarization layer 140.

FIG. 6 is a schematic cross-sectional view of a first substrate in a liquid crystal display panel of Embodiment 3. As shown in FIG. 6, the liquid crystal display panel 1 of the present embodiment includes a radical-trapping layer 145 having a radical-trapping function between the CF layer 130 and the planarization layer 140. The radical-trapping layer 145 becomes relatively stable by capturing radicals and is therefore capable of trapping radicals generated from other compounds, thereby enhancing light stability. Therefore, radicals generated in the planarization layer 140 upon irradiation with polarized ultraviolet light can be trapped by the radical-trapping layer 145. As a result, degradation of the CF layer 130 can be suppressed.

The radical-trapping layer 145 may be any layer that can trap radicals generated upon photoirradiation, particularly ultraviolet irradiation, and preferably contains a radical-trapping polymer having at least one group selected from the group consisting of hindered amine groups and hydrazyl radical groups. This configuration can achieve an even higher rate of radical trapping.

The radical-trapping layer polymer is preferably an imide-based polymer, a siloxane-based polymer, an amide-based polymer, an acrylic-based polymer, or a methacrylic-based polymer. Such a radical-trapping layer polymer can remain stable in a film and enables a high rate of radical trapping.

The radical-trapping layer polymer preferably has a structure represented by the following chemical formula (P1). Such a radical-trapping layer polymer can remain stable in a film and enables a high rate of radical trapping.

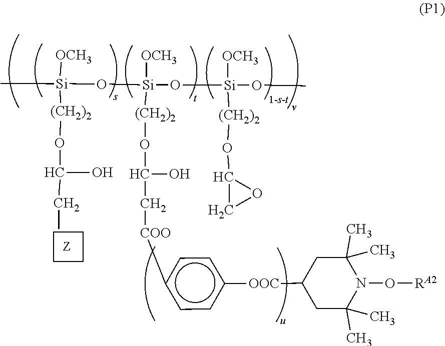

In the formula, s and t represent mass fractions of respective structural units in a main chain, s represents a real number greater than 0 and 0.5 or less, t represents a real number of 0.03 or greater and 0.3 or less, s+t<1, u represents an integer of 0 or greater and 18 or less, v represents an integer of 3 or greater, and Z represents a C3-C25 alkyl group.

In the chemical formula (P1), s is a real number greater than 0 and 0.5 or less. This configuration can improve the radical-trapping effect. s preferably represents a real number of 0.05 or greater and 0.5 or less, and more preferably represents 0.5.

In the chemical formula (P1), t represents a real number of 0.03 or greater and 0.3 or less. This configuration can maintain the high rate of radical trapping. t preferably represents a real number of 0.1 or greater and 0.3 or less, more preferably a real number of 0.15 or greater and 0.3 or less.

In the chemical formula (P1), s and t satisfy the relationship s+t<1. This configuration can uniformly distribute the radical-trapping layer polymer in a film. s and t preferably satisfy the relationship 0.03<s+t<0.8, more preferably the relationship 0.15<s+t<0.8.

In the chemical formula (P1), u represents an integer of 0 or greater and 18 or less. This configuration enables effective trapping of radicals. u preferably represents an integer of 1 or greater and 18 or less, more preferably an integer of 4 or greater and 12 or less. In the chemical formula (P1), v represents an integer of 3 or greater. This configuration can uniformly distribute the radical-trapping layer polymer in a film. The upper limit of v is not limited. v is, for example, an integer of 100 or less.

Z is a C3-C25 alkyl group. This configuration can uniformly distribute the radical-trapping layer polymer in a film. The C3-C25 alkyl group may be linear (linear alkyl group), branched (branched alkyl group), or cyclic (cycloalkyl group).

The radical-trapping layer 145 preferably has a thickness greater than 0 nm and 300 nm or less. This configuration can increase the density of the functional group having a radical-trapping function contained in the radical-trapping polymer to a level higher than when the radical-trapping layer polymer is dispersed in a thick film (for example, a planarization layer 140 having a thickness of about 1.6 μm). As a result, the radical-trapping layer 145 can more effectively trap radicals, more effectively suppressing degradation of the CF layer 130.

### EXAMPLES

Hereinafter, examples will be described. The present invention is not limited to these examples.

### Production of Liquid Crystal Display Panel of Example 1-1

A liquid crystal display panel 1 of Example 1-1 corresponding to the liquid crystal display panel 1 of Embodiment 1 was produced. Specifically, an FFS-mode liquid crystal display panel 1 was produced using a pair of substrates, namely the first substrate 10 (referred to also as an active substrate) shown in FIG. 2 and the second substrate 20 (referred to also as a counter substrate) including no color filter layer. The color materials of the CF layer 130 in the first substrate 10 are composed of three colors, namely red, green, and blue. The panel resolution was 1400 ppi (sub-pixel (sub-pixel 1P) size: 6 μm×9 μm). The CF layer 130 had a thickness of 1.7 mm.

In order to form the planarization layer 140, a resist composition that contains a positive resist, a crosslinkable polymer having a crosslinkable group, and a hydroxy compound was applied to the CF layer 130, followed by a pre-bake at around 100 °C. Subsequently, a pattern was formed by ultraviolet light exposure and development, followed by a post-bake, thereby forming the planarization layer 140. The post-bake was performed at 200 °C for 30 minutes to adjust the taper angle θ to 30°. The planarization layer 140 had a thickness of 1.5 mm.

The positive resist contained in the resist composition was a compound having, as a naphthoquinone diazide group, a structure in which R in the chemical formula (PLN1) was a methyl group.

The crosslinkable polymer having a crosslinkable group contained in the resist composition was an imide-based polymer having an epoxy group as the crosslinkable group in a specific amount. Specifically, a compound was used in which X in the chemical formula (PLN2) was represented by the chemical formula (X-1), Y was represented by the chemical formula (Y-1), L was a propylene group, p was 20 or greater, and q was 0.15.

The hydroxy compound contained in the resist composition was a compound serving as the novolac resin in which n in the chemical formula (PLN3) was 15 or greater.

Furthermore, on the planarization layer 140, the connection electrodes 100X and the pixel electrodes 150 were formed using ITO. The connection electrodes 100X and the pixel electrodes 150 had a thickness of 50 nm. The overlap length 100Y1 was 2.0 (±0.1) μm.

In addition, on the pixel electrodes 150, a common electrode was formed using ITO via an insulating film. The common electrode had a thickness of 50 nm.

The first alignment film 41 and the second alignment film 42 were respectively formed by applying an alignment film material including a polymer (polyimide) having a cyclobutane ring (cyclobutane group) represented by the following chemical formula (AL1) to the first substrate 10 and the second substrate 20, and irradiating the alignment film material with polarized ultraviolet light having a central wavelength of 250 nm at 3 J/cm².

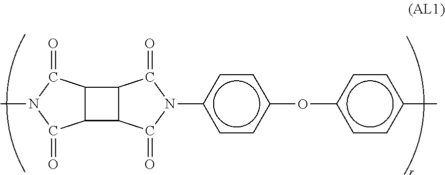

In the formula, r represents a degree of polymerization (an integer of 10 or greater).

The liquid crystal layer 30 contained the liquid crystal molecules 300 with a positive anisotropy of dielectric constant. The liquid crystal layer 30 had a thickness (cell thickness) of 1.5 mm.

### Production of Liquid Crystal Display Panels of Examples 1-2 and 1-3 and Comparative Examples 1-1 and 1-2

Liquid crystal display panels of Examples 1-2 and 1-3 and Comparative Examples 1-1 and 1-2 were produced in the same manner as in Example 1-1, except that the taper angles θ were set to the respective angles shown in the following Table 1. The overlap lengths 100Y1 were 2.0 (±0.1) μm in the liquid crystal display panels of Examples 1-2 and 1-3 and Comparative Examples 1-1 and 1-2.

In Example 1-2, the taper angle θ was set to 37° by performing a post-bake at 220 °C for 30 minutes.

In Example 1-3, the taper angle θ was set to 50° by performing a post-bake at 235 °C for 30 minutes.

In Comparative Example 1-1, the taper angle θ was set to 27° by performing a post-bake at 160 °C for 30 minutes.

In Comparative Example 1-2, the taper angle θ was set to 55° by performing a post-bake at 250 °C for 30 minutes.

TABLE 1

| | | Transmittance | Molecular |
|---|---|---|---|
| | Taper angle | (Y) | weight |
| Planarization | θ | 400 to 700 nm | distribution |
| layer | (°) | (%) | (M_{w}/Mₙ) |
| Comparative | 27 | 94.1 | 28 |
| Example 1-1 | | | |
| Example 1-1 | 30 | 96.0 | 19 |
| Example 1-2 | 37 | 96.8 | 17 |
| Example 1-3 | 50 | 96.2 | 13 |
| Comparative | 55 | 94.5 | 8.2 |
| Example 1-2 | | | |

### Evaluation of Liquid Crystal Display Panels of Examples 1-1 to 1-3 and Comparative Examples 1-1 and 1-2

Only the planarization layers were removed from the high-resolution COA panels (liquid crystal display panels) produced in Examples 1-1 to 1-3 and Comparative Examples 1-1 and 1-2, and the transmittance of each planarization layer (transmittance (Y)) was measured. The transmittance of each planarization layer was specifically measured by transmission spectral measurement using the transmittance at 550 nm. Also, the molecular weight distribution of the planarization layer was determined by gel permeation chromatography. The molecular weight distribution of the planarization layer was specifically determined by dissolving the planarization layer in a non-polar solvent (e.g., THF, toluene) and analyzing the resulting solution by gel permeation chromatography. Here, the reference polymer was polystyrene. The results are shown in Table 1.

As shown in Table 1, in Examples 1-1 to 1-3 and Comparative Examples 1-1 and 1-2, the taper angle θ was set to a range of 27° to 55° by adjusting the conditions of forming a planarization layer. In Examples 1-1 to 1-3 in which the taper angle θ was within the range of 30° to 50°, the transmittance of the planarization layer (transmittance (Y)) was 95% or higher. However, in Comparative Examples 1-1 and 1-2 in which the taper angle θ was less than 30° or greater than 50°, the transmittance of the planarization layer (transmittance (Y)) was below 95%.

As shown in Comparative Example 1-1, when the taper angle θ was small, the post-bake was insufficient, so that the compound containing a naphthoquinone diazide group serving as the positive resist did not fully react, presumably resulting in low transmittance of the planarization layer. Furthermore, insufficient crosslinking presumably caused the molecular weight distribution of the planarization layer to exceed 20. In Comparative Example 1-2 in which the taper angle θ was greater than 50°, the amount of positive resist used was increased to promote crosslinking, presumably resulting in decreased transmittance of the planarization layer. However, the molecular weight distribution of the planarization layer in Comparative Example 1-2 was less than 10, which was comparatively small.

For the liquid crystal display panels of Examples 1-1 to 1-3 and Comparative Examples 1-1 and 1-2, transmittance measurements, driving performance evaluations (rising response time and falling response time), and determination of occurrence of open-circuit defects in the connection electrodes were conducted. The transmittance of each liquid crystal display panel was determined by transmission spectral measurement using the transmittance at 550 nm. The rising response time and the falling response time were measured at 25 °C using a liquid crystal evaluation system (LCD-5200, Otsuka Electronics Co., Ltd.). The results are shown in the following Table 2.

TABLE 2

| | Transmittance | | | |
|---|---|---|---|---|
| | of liquid | | | Open-circuit |
| | crystal | Response time | | defects in |
| | display | Rise time | Fall time | connection |
| | panel (%) | (ms) | (ms) | electrodes |
| Comparative | 0.7 | 1.8 | 2.0 | Not occurred |
| Example 1-1 | | | | |
| Example 1-1 | 1.2 | 1.8 | 2.0 | Not occurred |
| Example 1-2 | 1.3 | 1.8 | 2.0 | Not occurred |
| Example 1-3 | 1.4 | 1.8 | 2.0 | Not occurred |
| Comparative | Not measurable due to open circuit | | | |
| Example 1-2 | | | | |

As shown in Table 2, the transmittance of the liquid crystal display panel of each of Examples 1-1 to 1-3 in which the taper angle θ was 30° or greater and 50° or less was 1.0% or higher, whereas the transmittance of the liquid crystal display panel of Comparative Example 1-1 in which the taper angle θ was less than 30° was below 1.0%. In the liquid crystal display panel of Comparative Example 1-2 in which the taper angle θ exceeded 50°, open-circuit defects occurred.

The response times were equivalent across Examples 1-1 to 1-3 and Comparative Example 1-1.

The above results show that setting the taper angle θ to 30° or greater and 50° or less and setting the overlap length to 1 μm or greater and 3 μm or less enabled the maintenance of high transmittance of the liquid crystal display panel (in the present examples, 1.0% or higher) and the suppression of open-circuit defects in the connection electrodes.

### Production of Liquid Crystal Display Panel of Example 2-1

A liquid crystal display panel 1 of Example 2-1 corresponding to the liquid crystal display panel 1 of Embodiment 2 was produced. The liquid crystal display panel of Example 2-1 was produced in the same manner as in Example 1-1, except that the taper angle θ, the planarization layer, the first alignment film, and the second alignment film were different.

In Example 2-1, 4 wt % of a compound represented by the following chemical formula (A3) was added as the radical scavenger 140A to the planarization layer, and the taper angle θ was adjusted to 35° by performing a post-bake at 220 °C for 30 minutes. The overlap length 100Y1 was 2.0 (±0.1) μm in the liquid crystal display panel of Example 2-1.

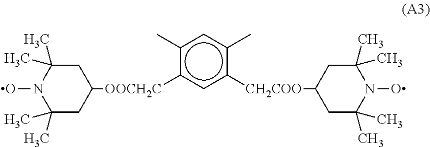

The first alignment film 41 and the second alignment film 42 were formed by applying an alignment film material containing a polymer (polyimide) having an azobenzene group represented by the following chemical formula (AL2) to the first substrate 10 and the second substrate 20, and irradiating the material with polarized ultraviolet light having a central wavelength of 360 nm at 5 J/cm².

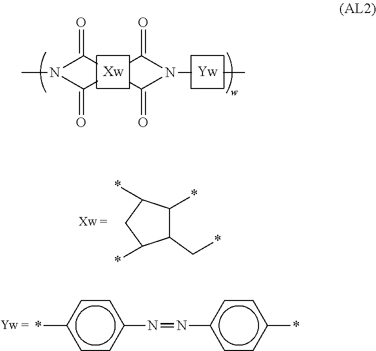

In the formula, w is the degree of polymerization (integer of 10 or greater).

### Production of Liquid Crystal Display Panels of Examples 2-2 and 2-3 and Comparative Example 2-1

Liquid crystal display panels of Examples 2-2 and 2-3 and Comparative Example 2-1 were produced in the same manner as in Example 2-1, except that the amount of the compound represented by the chemical formula (A3) serving as the radical scavenger in the planarization layer, and the taper angle θ were set to the values shown in the following Table 3. The overlap lengths 100Y1 were 2.0 (±0.1) μm in the liquid crystal display panels of Examples 2-2 and 2-3 and Comparative Example 2-1.

In Example 2-2, the amount of the radical scavenger in the planarization layer was adjusted to 8 wt %, and the taper angle θ was set to 33° by performing a post-bake at 220 °C for 30 minutes.

In Example 2-3, the amount of the radical scavenger in the planarization layer was adjusted to 12 wt %, and the taper angle θ was set to 31° by performing a post-bake at 220 °C for 30 minutes.

In Comparative Example 2-1, the amount of the radical scavenger in the planarization layer was adjusted to 16 wt %, and the taper angle θ was set to 28° by performing a post-bake at 220 °C for 30 minutes.

TABLE 3

| | Amount of | | | |
|---|---|---|---|---|
| | radical | | Transmittance | Molecular |
| | scavenger in | Taper angle | (Y) | weight |
| | planarization | θ | 400 to 700 nm | distribution |
| | layer (wt %) | (°) | (%) | (M_{w}/Mₙ) |
| Example 1-2 | 0 | 37 | 96.8 | 17 |
| Example 2-1 | 4 | 35 | 96.5 | 18 |
| Example 2-2 | 8 | 33 | 96.0 | 18 |
| Example 2-3 | 12 | 31 | 95.5 | 20 |
| Comparative | 16 | 28 | 94.5 | 23 |
| Example 2-1 | | | | |

### Evaluation of Liquid Crystal Display Panels of Examples 1-2 and 2-1 to 2-3 and Comparative Example 2-1

Only the planarization layers were removed from the high-resolution COA panels (liquid crystal display panels) produced in Examples 1-2 and 2-1 to 2-3 and Comparative Example 2-1, and the transmittance of each planarization layer was measured. The molecular weight distribution of the planarization layer was determined by gel permeation chromatography. The results are shown in Table 3.

As shown in Table 3, when the amount of the radical scavenger in the planarization layer was 12 wt % or less, the taper angle θ could be set to 30° or greater. In contrast, when the amount of the radical scavenger in the planarization layer was 16 wt %, the taper angle θ was less than 30°.

Here, as shown in Table 3, the molecular weight distribution of the planarization layer broadened as the amount of the radical scavenger increased. This is presumably because the photoreactivity of the compound having a naphthoquinone diazide group, which serves as the positive resist, decreased with increasing amount of the radical scavenger, thereby reducing crosslinking during the post-bake of the planarization layer. These results indicate that increasing the amount of the radical scavenger reduces crosslinking during the post-bake of the planarization layer, that is, results in a broader molecular weight distribution and a decreased taper angle θ.

When the amount of the radical scavenger in the planarization layer was 12 wt % or less, the transmittance of the planarization layer was 95.0% or higher. Meanwhile, when the amount of the radical scavenger in the planarization layer was 16 wt %, the transmittance of the planarization layer was lower than 95.0%.

For the liquid crystal display panels of Examples 1-2 and 2-1 to 2-3 and Comparative Example 2-1, transmittance measurements, driving performance evaluations (rising response time and falling response time), and voltage holding ratio (VHR) measurements were conducted. The results are shown in the following Table 4.

The VHR measurement of each liquid crystal display panel was performed as described below. That is, for each liquid crystal display panel to be evaluated, the VHR (initial value) was measured at 1 V and 70 °C using a VHR measurement system model 6254 available from Toyo Corporation. Thereafter, a high-temperature operation was conducted at 70 °C for 1000 hours. For each liquid crystal display panel after the high-temperature operation, the VHR was measured under the same conditions as those used for the measurement before the high-temperature operation.

TABLE 4

| | Transmittance | | | | |
|---|---|---|---|---|---|
| | of liquid | | | | |
| | crystal | Response time | | VHR (%) | |
| | display | Rise time | Fall time | | After |
| | panel (%) | (ms) | (ms) | Initial | 1000 h |
| Example 1-2 | 1.3 | 1.8 | 2.0 | 98.8 | 98.0 |
| Example 2-1 | 1.3 | 1.8 | 2.0 | 99.4 | 98.8 |
| Example 2-2 | 1.2 | 1.8 | 2.0 | 99.4 | 99.1 |
| Example 2-3 | 1.0 | 1.8 | 2.0 | 99.4 | 99.1 |
| Comparative | 0.9 | 1.8 | 2.0 | 99.4 | 99.1 |
| Example 2-1 | | | | | |

As shown in Examples 1-2 and 2-1 to 2-3 in Table 3 and Table 4, when the amount of the radical scavenger in the planarization layer was 12 wt % or less, the transmittance of the liquid crystal display panel was 1.0% or higher. However, as shown in Comparative Example 2-1, when the amount of the radical scavenger in the planarization layer was 16 wt %, the transmittance of the liquid crystal display panel was lower than 1.0%.

Meanwhile, the response times were equivalent across the liquid crystal display panels of Examples 1-2 and 2-1 to 2-3 and Comparative Example 2-1.

The VHR before aging (initial value) at 70 °C was 98.8% in Example 1-2 in which the radical scavenger was not contained in the planarization layer. Meanwhile, the VHR before aging in Examples 2-1 to 2-3 in which the radical scavenger was contained in the planarization layer was 99.4%, which was higher than that in Example 1-2.

In Example 1-2 in which the planarization layer did not contain a radical scavenger, polarized ultraviolet light applied during the photoalignment treatment degraded the planarization layer and the CF layer positioned under the photoalignment film and generated impurities. The impurities presumably contaminated at least one of the alignment film (specifically, first alignment film) or the liquid crystal layer, thereby decreasing the initial VHR. In contrast, in Examples 2-1 to 2-3 in which the planarization layer contained the radical scavenger, presumably, degradation of the planarization layer and the CF layer due to the polarized ultraviolet light was suppressed, which in turn suppressed the contamination of the alignment film (specifically, first alignment film) and the liquid crystal layer with the impurities. Therefore, the initial VHR values in Examples 2-1 to 2-3 were higher than that in Example 1-2.

In addition, the VHR after operation at 70 °C for 1000 hours (also referred to simply as VHR after 1000 hours) was 98.0% in Example 1-2 in which the planarization layer did not contain a radical scavenger. In contrast, the VHR after 1000 hours in each of Examples 2-1 to 2-3 in which the planarization layer contained a radical scavenger was 98.8% or higher, which was higher than that in Example 1-2.

In Example 1-2 in which the planarization layer did not contain a radical scavenger, long-term use at high temperatures degraded the planarization layer and the CF layer and generated impurities. The impurities presumably migrated into the alignment film (first alignment film) and the liquid crystal layer, thereby decreasing the VHR after 1000 hours. In contrast, in Examples 2-1 to 2-3 in which the planarization layer contained the radical scavenger, presumably, degradation of the planarization layer and the CF layer due to the polarized ultraviolet light was suppressed, which in turn suppressed the contamination of the alignment film (specifically, first alignment film) and the liquid crystal layer with the impurities. Therefore, the stable VHR after the long-term use was presumably achieved in the liquid crystal display panels of Examples 2-1 to 2-3.

The above results confirmed that the preferred amount of the radical scavenger in the planarization layer 140 is 12 wt % or less.

### Production of Liquid Crystal Display Panel of Example 3-1

A liquid crystal display panel 1 of Example 3-1 corresponding to the liquid crystal display panel 1 of Embodiment 3 was produced. The liquid crystal display panel of Example 3-1 was produced in the same manner as in Example 1-1, except that the taper angle θ, the first alignment film, and the second alignment film were different and that the radical-trapping layer was included.

In Example 3-1, the taper angle θ was adjusted to 37° by performing a post-bake at 220 °C for 30 minutes. The overlap length 100Y1 was 2.0 (±0.1) μm in the liquid crystal display panel of Example 3-1.

In the same manner as in Example 2-1, the first alignment film 41 and the second alignment film 42 were formed by applying an alignment film material containing a polymer (polyimide) having an azobenzene group represented by the chemical formula (AL2) to the first substrate 10 and the second substrate 20, and irradiating the material with polarized ultraviolet light having a central wavelength of 360 nm at 5 J/cm².

In Example 3-1, the radical-trapping layer 145 having a radical-trapping function was further disposed between the CF layer 130 and the planarization layer 140. The radical-trapping layer 145 contained a radical-trapping layer polymer represented by the chemical formula (P1) wherein s was 0.5, t was 0.3, u was 4, v was 10 or greater, and Z was a C12 alkyl group (—C₁₂H₂₅). The radical-trapping layer 145 had a thickness of 100 nm.

### Production of Liquid Crystal Display Panels of Examples 3-2 and 3-3

Liquid crystal display panels of Examples 3-2 and 3-3 were produced in the same manner as in Example 3-1, except that the thickness of each radical-trapping layer 145 was changed to the corresponding thickness shown in the following Table 5. The overlap lengths 100Y1 were 2.0 (±0.1) μm in the liquid crystal display panels of Examples 3-2 and 3-3.

TABLE 5

| | Thickness | Taper | Transmittance | Molecular |
|---|---|---|---|---|
| | of polymer | angle | (Y) | weight |
| | layer | θ | 400 to 700 nm | distribution |
| | (nm) | (°) | (%) | (M_{w}/Mₙ) |
| Example 1-2 | 0 (none) | 37 | 96.8 | 17 |
| Example 3-1 | 100 | 37 | 96.4 | 17 |
| Example 3-2 | 200 | 37 | 96.0 | 17 |
| Example 3-3 | 300 | 37 | 95.3 | 17 |

### Evaluation of Liquid Crystal Display Panels of Examples 1-2 and 3-1 to 3-3

The planarization layers and the radical-trapping layers were removed from the high-resolution COA panels (liquid crystal display panels) produced in Examples 1-2 and 3-1 to 3-3, and the transmittance of each laminate of a planarization layer and a radical-trapping layer was measured. The molecular weight distribution of each planarization layer was determined by gel permeation chromatography. The results are shown in Table 5.

As shown in Examples 3-1 to 3-3 in Table 5, disposing the radical-trapping layer having a thickness of 300 nm or less on the CF layer (under the planarization layer) enabled a transmittance of the laminate of a planarization layer and a radical-trapping layer of 95.0% or higher. When the thickness of the radical-trapping layer was greater than 300 nm, the radical-trapping layer may be thick and the transmittance of the laminate of a planarization layer and a radical-trapping layer may be low.

Table 5 shows that the thickness of the radical-trapping layer does not affect the taper angle θ of the planarization layer and the molecular weight distribution of the planarization layer.

For the liquid crystal display panels of Examples 1-2 and 3-1 to 3-3, transmittance measurements, driving performance evaluations (rising response time and falling response time), and VHR measurements were conducted. The results are shown in the following Table 6.

TABLE 6

| | Transmittance | | | | |
|---|---|---|---|---|---|
| | of liquid | | | | |
| | crystal | Response time | | VHR (%) | |
| | display | Rise time | Fall time | | After |
| | panel (%) | (ms) | (ms) | Initial | 1000 h |
| Example 1-2 | 1.3 | 1.8 | 2.0 | 98.8 | 98.0 |
| Example 3-1 | 1.3 | 1.8 | 2.0 | 99.4 | 98.8 |
| Example 3-2 | 1.2 | 1.8 | 2.0 | 99.4 | 98.9 |
| Example 3-3 | 1.0 | 1.8 | 2.0 | 99.4 | 99.0 |

As shown in Examples 1-2 and 3-1 to 3-3 in Table 5 and Table 6, when the thickness of the radical-trapping layer was 300 nm or less, the transmittance of the liquid crystal display panel 1 was 1.0% or higher. However, when the thickness of the radical-trapping layer was greater than 300 nm, the radical-trapping layer may become thick and the transmittance of the laminate of a planarization layer and a radical-trapping layer may be low, which may result in a decrease in transmittance of the liquid crystal display panel.

Meanwhile, the response times were equivalent across the liquid crystal display panels 1 of Examples 1-2 and 3-1 to 3-3.

The VHR before aging (initial value) at 70 °C was 98.8% in Example 1-2 in which no radical-trapping layer was used. Meanwhile, the VHR before aging in Examples 3-1 to 3-3 in which a radical-trapping layer was used was 99.4%, which was higher than that in Example 1-2.

In Example 1-2 in which no radical-trapping layer was used, polarized ultraviolet light applied during the photoalignment treatment degraded the planarization layer and the CF layer positioned under the photoalignment film and generated impurities. The impurities presumably contaminated at least one of the alignment film (specifically, first alignment film) or the liquid crystal layer, thereby decreasing the initial VHR. In contrast, in Examples 3-1 to 3-3 in which a radical-trapping layer was used, presumably, degradation of the planarization layer and the CF layer due to the polarized ultraviolet light was suppressed, which in turn suppressed the contamination of the alignment film (specifically, first alignment film) and the liquid crystal layer with the impurities. Therefore, the initial VHR values in Examples 3-1 to 3-3 were higher than that in Example 1-2.

In addition, the VHR after operation at 70 °C for 1000 hours (also referred to simply as VHR after 1000 hours) was 98.0% in Example 1-2 in which no radical-trapping layer was used. In contrast, the VHR after 1000 hours in each of Examples 3-1 to 3-3 in which a radical-trapping layer was used was 98.8% or higher, which was higher than that in Example 1-2.

In Example 1-2 in which no radical-trapping layer was used, long-term use at high temperatures degraded the planarization layer and the CF layer and generated impurities. The impurities presumably migrated into the alignment film (first alignment film) and the liquid crystal layer, thereby decreasing the VHR after 1000 hours. In contrast, in Examples 3-1 to 3-3 in which a radical-trapping layer was used, presumably, degradation of the planarization layer and the CF layer due to the polarized ultraviolet light was suppressed, which in turn suppressed the contamination of the alignment film (specifically, first alignment film 41) and the liquid crystal layer with the impurities. Therefore, the stable VHR after the long-term use was presumably achieved in the liquid crystal display panels of Examples 3-1 to 3-3.

The VHR in Example 3-3 in which the thickness of the radical-trapping layer was 400 nm was equivalent to that in Examples 3-1 to 3-3 in which the thickness was 300 nm or less. However, the liquid crystal display panel 1 of Example 3-3 may cause a decrease in transmittance. Therefore, the preferred thickness of the radical-trapping layer was confirmed to be 300 nm or less.

### Production of Liquid Crystal Display Panels of Examples 4-1 and 4-2 and Comparative Examples 4-1 and 4-2

Liquid crystal display panels of Examples 4-1 and 4-2 and Comparative Examples 4-1 and 4-2 were produced, which had the same configuration as that of Example 1-1 except that the overlap lengths 100Y1 were different. The overlap lengths 100Y1 were set to the desired values by adjusting the patterning (optimizing the mask size) during electrode formation. The overlap length 100Y1 in Example 4-1 was 1.0 μm. The overlap length 100Y1 in Example 4-2 was 3.0 μm. The overlap length 100Y1 in Comparative Example 4-1 was 0.9 μm. The overlap length 100Y1 in Comparative Example 4-2 was 3.1 μm.

Only the planarization layers were removed from the high-resolution COA panels (liquid crystal display panels) produced in Examples 4-1 and 4-2 and Comparative Examples 4-1 and 4-2, and the transmittance of each planarization layer was measured. The molecular weight distribution of the planarization layer was determined by gel permeation chromatography. The results are shown in Table 7.

TABLE 7

| | | | Transmittance | Molecular |
|---|---|---|---|---|
| | Overlap | Taper angle | (Y) | weight |
| | length | θ | 400 to 700 nm | distribution |
| | (μm) | (°) | (%) | (M_{w}/Mₙ) |
| Example 4-1 | 1.0 | 30 | 96.0 | 19 |
| Example 4-2 | 3.0 | 30 | 95.3 | 19 |
| Comparative | 0.9 | 30 | 96.4 | 19 |
| Example 4-1 | | | | |
| Comparative | 3.1 | 30 | 95.1 | 19 |
| Example 4-2 | | | | |

For the liquid crystal display panels of Examples 4-1 and 4-2 and Comparative Examples 4-1 and 4-2, transmittance measurements, driving performance evaluations (rising response time and falling response time), and voltage holding ratio (VHR) measurements were conducted. The results are shown in the following Table 8.

TABLE 8

| | Transmittance | | | | |
|---|---|---|---|---|---|
| | of liquid | | | | |
| | crystal | Response time | | VHR (%) | |
| | display | Rise time | Fall time | | After |
| | panel (%) | (ms) | (ms) | Initial | 1000 h |
| Example 4-1 | 1.2 | 1.8 | 2.0 | 99.0 | 98.8 |
| Example 4-2 | 1.0 | 1.8 | 2.0 | 99.0 | 98.8 |
| Comparative | Not measurable due to open circuit | | | | |
| Example 4-1 | | | | | |
| Comparative | 0.9 | 1.8 | 2.0 | 99.0 | 98.8 |
| Example 4-2 | | | | | |

Although embodiments of the present disclosure and modifications thereof have been described, the scope of the present disclosure is not limited to such embodiments and modifications. Various forms and modifications thereof can be made without departing from the gist of the present disclosure. In addition, the plurality of elements disclosed in the embodiments and modifications thereof described above may be altered as appropriate. For example, a certain element among all the elements shown in one embodiment or modification thereof may be added to the elements of another embodiment or modification thereof, or some elements among all the elements shown in one embodiment or modification thereof may be removed from the embodiment or modification thereof.

The drawings are schematic illustrations in which the elements are mainly shown for ease of understanding of the disclosure. Therefore, the thickness, length, number, spacing, and the like of the respective elements illustrated in the drawings may differ from actual values for convenience of illustration. Moreover, the configurations of the respective elements described in the above embodiments are merely examples and are not intended to be limiting, and various modifications may be made without substantially departing from the effects of the present disclosure.

What is claimed is:

1. A liquid crystal display panel comprising:
a first substrate;
a second substrate opposite to the first substrate; and
a liquid crystal layer sandwiched between the first substrate and the second substrate, the first substrate including, sequentially toward the liquid crystal layer:
a switching element;
a color filter layer;
a planarization layer formed from a resist composition that contains a positive resist and a crosslinkable polymer having a crosslinkable group; and
a pixel electrode,
the first substrate further including:
a connection electrode connecting the switching element and the pixel electrode via an opening formed through the color filter layer and the planarization layer; and
a connection region in which the pixel electrode and the connection electrode are in contact with each other,
wherein the planarization layer has a taper angle θ of 30° or greater and 50° or less at the opening, and
an overlap length, defined as a length from one end to the other end of the connection region in a vertical direction of a screen of the liquid crystal display panel or in a horizontal direction of the screen, is 1 μm or greater and 3 μm or less.

2. The liquid crystal display panel according to claim 1, further comprising a photoalignment film between the first substrate and the liquid crystal layer,
wherein the photoalignment film contains a photoalignment film polymer having at least one functional group selected from the group consisting of a photodegradable functional group, a photodimerizable functional group, and a photoisomerizable functional group.

3. The liquid crystal display panel according to claim 2,
wherein the photoalignment film polymer has at least one group selected from the group consisting of a cyclobutane group, an azobenzene group, a cinnamate group, and a coumarin group.

4. The liquid crystal display panel according to claim 1,
wherein the planarization layer exhibits a molecular weight distribution of 10 or greater and 20 or less.

5. The liquid crystal display panel according to claim 1,
wherein the positive resist is at least one compound selected from the group consisting of naphthoquinone diazide and a naphthoquinone diazide derivative.

6. The liquid crystal display panel according to claim 1,
wherein the planarization layer contains a radical scavenger having a radical-trapping group.

7. The liquid crystal display panel according to claim 6,
wherein the radical-trapping group is a hindered amine group.

8. The liquid crystal display panel according to claim 7,
wherein the hindered amine group has at least one structure selected from the group consisting of structures represented by the following chemical formula (A11) and structures represented by the following chemical formula (A12): 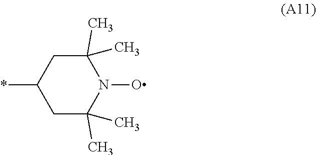
wherein * represents a bonding site, 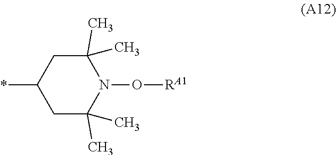
wherein R^{A1} represents a monovalent alkyl group, and * represents a bonding site.

9. The liquid crystal display panel according to claim 6,
wherein the radical-trapping group is a hydrazyl radical group.

10. The liquid crystal display panel according to claim 9,
wherein the hydrazyl radical group has a structure represented by the following chemical formula (B): 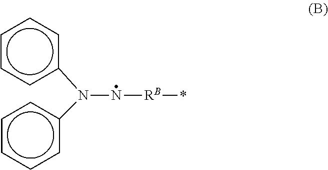
wherein R^{B} represents a divalent organic group, and * represents a bonding site.

11. The liquid crystal display panel according to claim 6,
wherein the planarization layer contains the radical scavenger in an amount greater than 0 wt % and less than 16 wt %.

12. The liquid crystal display panel according to claim 1, further comprising a radical-trapping layer having a radical-trapping function between the color filter layer and the planarization layer.

13. The liquid crystal display panel according to claim 12,
wherein the radical-trapping layer contains a radical-trapping layer polymer having at least one group selected from the group consisting of hindered amine groups and hydrazyl radical groups.

14. The liquid crystal display panel according to claim 13,
wherein the radical-trapping layer polymer is an imide-based polymer, a siloxane-based polymer, an amide-based polymer, an acrylic-based polymer, or a methacrylic-based polymer.

15. The liquid crystal display panel according to claim 13,
wherein the radical-trapping layer polymer has a structure represented by the following chemical formula (P1): 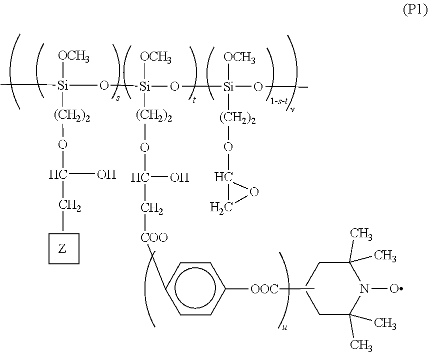
wherein s and t represent mass fractions of respective structural units in a main chain, s represents a real number greater than 0 and 0.5 or less, t represents a real number of 0.03 or greater and 0.3 or less, s+t<1, u represents an integer of 0 or greater and 18 or less, v represents an integer of 3 or greater, and Z represents a C3-C25 alkyl group.

16. The liquid crystal display panel according to claim 12,
wherein the radical-trapping layer has a thickness greater than 0 nm and 300 nm or less.

17. A method for producing a liquid crystal display panel including:
a first substrate including a switching element;
a second substrate opposite to the first substrate; and
a liquid crystal layer sandwiched between the first substrate and the second substrate,
the method comprising:
a color filter layer formation step including forming a color filter layer provided with a first opening above the switching element;
a planarization layer formation step including applying a resist composition that contains a positive resist and a crosslinkable polymer having a crosslinkable group to a side of the color filter layer opposite to the switching element, performing an exposure treatment and a development treatment, and then performing a heat treatment, thereby forming a planarization layer provided with a second opening that overlaps the first opening in a plan view;
a connection electrode formation step including forming a connection electrode that extends from the switching element to a surface of the planarization layer opposite to the color filter layer through an opening defined by the first opening and the second opening; and
a pixel electrode formation step including forming a pixel electrode that is in contact with the connection electrode, on a side of the connection electrode opposite to the planarization layer,
wherein the planarization layer has a taper angle θ of 30° or greater and 50° or less at the opening, and
an overlap length is 1 μm or greater and 3 μm or less, the overlap length being defined as a length, measured in a vertical direction of a screen of the liquid crystal display panel or in a horizontal direction of the screen, from one end to the other end of a connection region in which the connection electrode and the pixel electrode are in contact with each other.

18. The method for producing a liquid crystal display panel according to claim 17,
wherein the heat treatment in the planarization layer formation step is performed at 120 °C or higher and 350 °C or lower for 10 minutes or more and 90 minutes or less.
